(19) United States
(12) Patent Application Publication
(10) Pub. No.: US 2026/0082612 A1
(43) Pub. Date: Mar. 19, 2026

(54) Semiconductor Device and Methods of Formation

(71) Applicant: Taiwan Semiconductor Manufacturing Company, Ltd., Hsinchu (TW)

(72) Inventors: Minchia LEE, Hsinchu City (TW); Li-Wei YIN, Hsinchu City (TW); Kai-Min CHIEN, New Taipei City (TW); I-Hsiang MA, Hsinchu (TW); Kuo-Chin LIU, Ji-an Township (TW); Yih-Ann LIN, Jhudong Township (TW); Ryan Chia-Jen CHEN, Hsinchu (TW)

(73) Assignee: Taiwan Semiconductor manufacturing Company, Ltd., Hsinchu (TW)

(21) Appl. No.: 18/819,228

(22) Filed: Aug. 29, 2024

(51) Int. Cl. H10D 30/00; H01L 21/306; H10D 30/01; H10D 62/10

(52) U.S. Cl. CPC H10D 30/503; H10D 30/0193; H10D 62/121; H10P 50/642

(57) ABSTRACT

Nanostructure channels of a nanostructure transistor are etched during a nanosheet release process for removing sacrificial nanostructure layers between the nanostructure channels. The nanostructure channels are etched such that the thickness of the nanostructure channels at the edges of the nanostructure channels is less than the thickness of the nanostructure channels at the centers of the nanostructure channels. This results in the nanostructure channels having a sloped/tapered or curved cross-sectional profile between the centers and the edges of the nanostructure channels. The resultant cross-section profile provides larger openings between vertically adjacent nanostructure channels for depositing material of a gate structure of the nanostructure transistor between vertically adjacent nanostructure channels of the nanostructure transistor. The larger openings increase the gap-filling performance for forming the gate structure, which reduces the likelihood of (and/or size of) seams and/or voids in the gate structure between vertically adjacent nanostructure channels.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIG. 5 is a diagram of an example implementation of a source/drain region formation process described herein.

FIG. 6 is a diagram of an example implementation of an interlayer dielectric formation process described herein.

FIGS. 7A-7F are diagrams of an example implementation of a nanosheet release process described herein.

FIGS. 8A-8J are diagrams of an example implementation of a nanosheet release process described herein.

FIGS. 9A-9C are diagrams of an example implementation of a gate formation process described herein.

FIG. 10 is a diagram of an example of a semiconductor device described herein.

FIG. 11 is a diagram of an example of a semiconductor device described herein.

FIGS. 12 and 13 are flowcharts of example processes associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some nanostructure transistors (e.g., nanowire transistors, nanosheet transistors, gate-all-around (GAA) transistors, multi-bridge channel transistors, nanoribbon transistors, and/or other types of nanostructure transistors) include inner spacers between a source/drain region and a gate structure. The inner spacers may provide various process and/or performance benefits, such as electrical isolation between the source/drain region and the gate structure, and/or protections of the source/drain region from being etched during a replacement gate operation to replace sacrificial nanostructure layers with the gate structure.

However, the process of forming a gate structure around the nanostructure channels of a nanostructure transistor such that the gate structure wraps around the nanostructure channels can be challenging and may result in formation of defects in the gate structure. For example, vertically adjacent nanostructure channels of the nanostructure transistor may be spaced apart by small spaces to achieve a high density of nanostructure channels, and this may result in difficulty in filling in the spaces between the vertically adjacent nanostructure channels. As a result, seams or voids in the gate structure between the vertically adjacent nanostructure channels may form due to the poor gap-filling performance between the vertically adjacent nanostructure channels. The seams/voids may result in increased gate resistance and/or increased gate capacitance, thereby decreasing the performance of the nanostructure transistor.

In some implementations described herein, nanostructure channels of a nanostructure transistor are etched during a nanosheet release process for removing sacrificial nanostructure layers between the nanostructure channels. The nanostructure channels are etched such that the thickness of the nanostructure channels at the edges of the nanostructure channels is less than the thickness of the nanostructure channels at the centers of the nanostructure channels. This results in the nanostructure channels having a sloped/tapered or curved cross-sectional profile between the centers and the edges of the nanostructure channels. The resultant cross-section profile provides larger openings between vertically adjacent nanostructure channels for depositing material of a gate structure of the nanostructure transistor between vertically adjacent nanostructure channels of the nanostructure transistor. The larger openings increase the gap-filling performance for forming the gate structure, which reduces the likelihood of (and/or size of) seams and/or voids in the gate structure between vertically adjacent nanostructure channels. Thus, the techniques described herein may reduce gate resistance and/or gate capacitance of the nanostructure transistor, which may increase the performance of the nanostructure transistor.

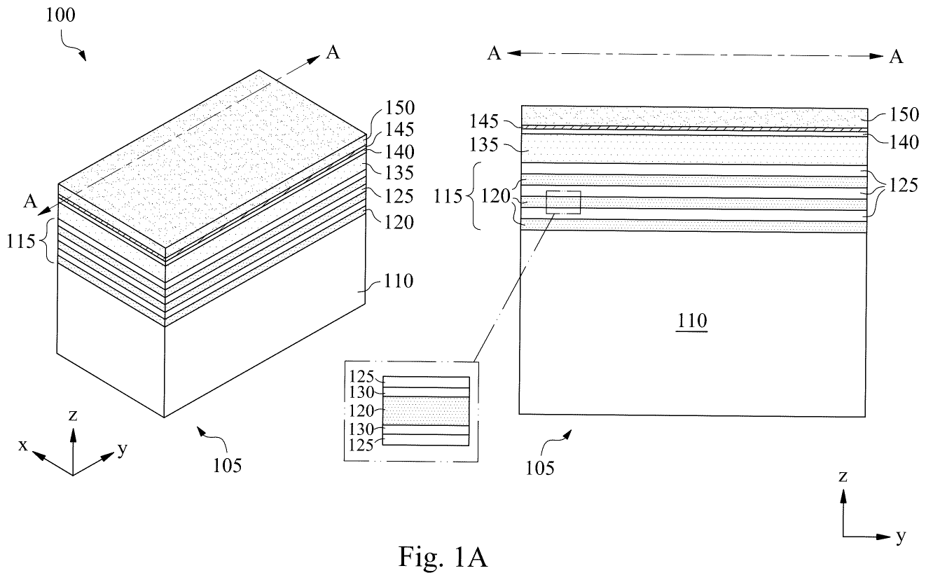

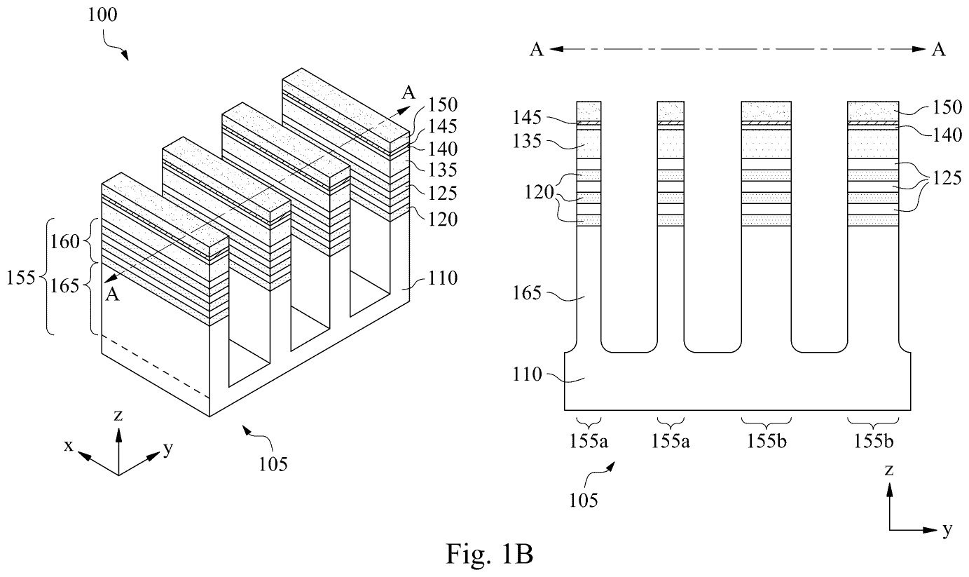

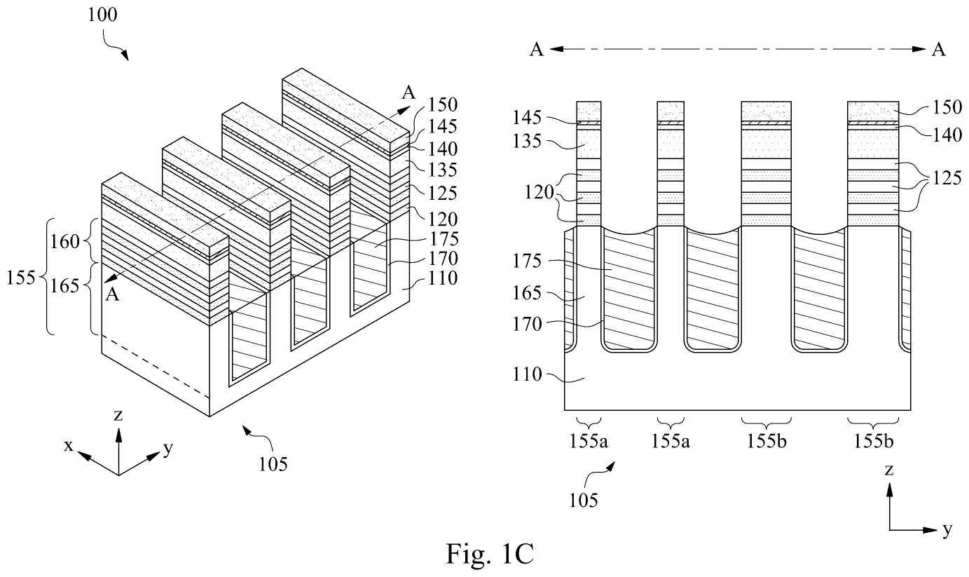

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIGS. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

As shown in a close-up view in FIG. 1A of a portion of the layer stack 115, intermixing between two or more nanostructure layers in the layer stack 115 may occur. For example, intermixing may occur between a sacrificial nanostructure layer 120 and a vertically adjacent nanostructure channel layer 125. The intermixing may result in diffusion of silicon (Si) and/or germanium (Ge) between the sacrificial nanostructure layer 120 and the nanostructure channel layer 125. Thus, intermixing layers 130 may be included between the sacrificial nanostructure layers 120 and the nanostructure channel layers 125. The intermixing layers 130 may include a region of silicon germanium (SiGe) having a greater concentration of silicon (Si) (e.g., due to the diffusion of silicon from the nanostructure channel layers 125 into the sacrificial nanostructure layers 120) than the concentration of germanium (Ge) in the intermixing layers 130.

One or more masking layers may be formed (e.g., using one or more deposition tools) on the layer stack 115. The masking layer(s) may include a hard mask (HM) layer 135, a capping layer 140, an oxide layer 145, and/or a nitride layer 150. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 155 that extend above the semiconductor substrate 110. The fin structures 155 may extend in an x-direction in the semiconductor device 105 and may be arranged in an y-direction in the semiconductor device 105. A fin structure 155 includes a portion 160 of the layer stack 115 over and/or on a fin portion 165 above the semiconductor substrate 110. The fin structures 155 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 155 may be formed to have different widths for different types of nanostructure transistors. As an example, a first subset of fin structures 155a may be formed for p-type nanostructure transistors (e.g., p-type metal oxide semiconductor (PMOS) nanostructure transistors), and a second subset of fin structures 155b may be formed for n-type nanostructure transistors (e.g., n-type metal oxide semiconductor (NMOS) nanostructure transistors). As another example, a first subset of fin structures 155a may be formed for nanostructure transistors that are configured to operate at lower voltages, and a second subset of fin structures 155b may be formed for nanostructure transistors that are configured to operate at higher voltages.

As shown in FIG. 1C, a liner 170 and STI regions 175 are formed between adjacent fin portions 165 of the fin structures 155. The liner 170 and the STI regions 175 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner 170 (e.g., using ALD or another conformal deposition technique), and may deposit a dielectric layer (e.g., using CVD, PVD, a ALD, and/or another suitable deposition technique) on the liner 170 such that the dielectric layer fully fills in the spaces between the fin structures 155 and extends above the tops of the fin structures 155. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 150. The nitride layer 150 functions as a CMP stop layer in the planarization operation. An etch tool may be used to then etch the dielectric layer to form the STI regions 175 such that the top surfaces of the STI region 175 are approximately co-planar with or below the bottom-most sacrificial nanostructure layer 120.

As indicated above, FIGS. 1A-1C are provided as an example. Other examples may differ from what is described with regard to FIGS. 1A-1C.

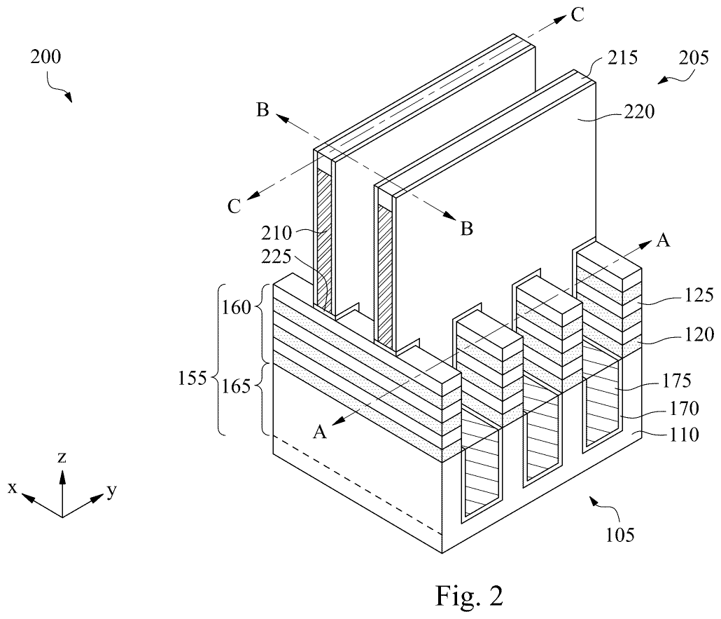

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 700 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 155 and portions of the STI regions 175. The dummy gate structures 205 extend in the x-direction and are arranged in the y-direction such that the dummy gate structures 205 are approximately perpendicular to the fin structures 155. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 155.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 155 in the source/drain areas of the semiconductor device 105. Cross-section B-B is in a y-z plane (referred to as an x-cut) perpendicular to the cross-section A-A, and is across the dummy gate structures 205 and along an underlying fin structure 155. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

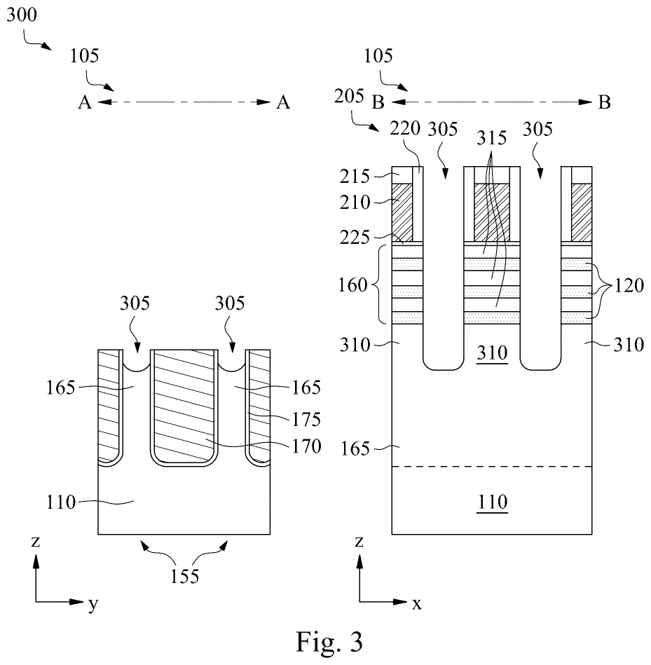

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 160 of a fin structure 155 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 165 of the fin structure 155. This results in formation of mesa regions 310 in the fin structure 155. The sidewalls of the portions of each source/drain recess 305 below the layer stack 115 correspond to sidewalls of mesa regions 310. A mesa region 310 (also referred to as pedestals) refers to a region of the fin portion 165 of the fin structure 155 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

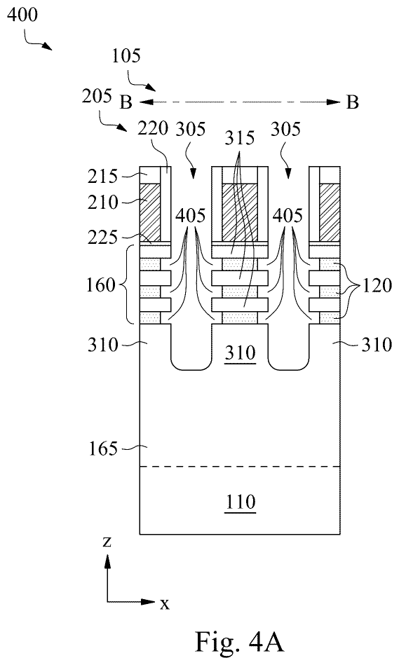

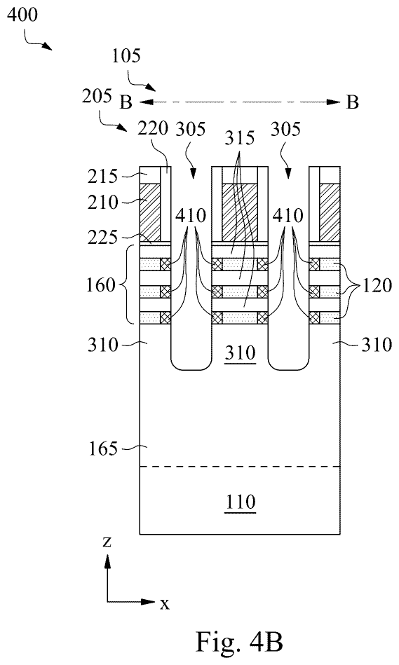

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are each illustrated from the perspective of the cross-sectional plane B-B in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in one or more first etch operations, thereby forming cavities 405 between the ends of the sacrificial nanostructure layers 120 that are exposed in the source/drain recesses 305. In particular, an etch tool may be use to laterally etch the ends of the sacrificial nanostructure layers 120 under the dummy gate structures 205 through the source/drain recesses 305 to form the cavities 405 between ends of the nanostructure channels 315.

In implementations where the sacrificial nanostructure layers 120 are silicon germanium (SiGe) and the nanostructure channels 315 are silicon (Si), the sacrificial nanostructure layers 120 are etched in the one or more first etch operations using a wet etchant such as a mixed solution including hydrogen peroxide (H₂O₂), acetic acid (CH₃COOH), and/or hydrogen fluoride (HF), followed by cleaning with water (H₂O). The mixed solution and the water may be provided into the source/drain recesses 305 to etch the sacrificial nanostructure layers 120 in the source/drain recesses 305. In some implementations, the etching by the mixed solution and cleaning by water is repeated for a plurality of cycles to form the cavities 405.

As shown in FIG. 4B, inner spacers 410 are formed in the cavities 405 between the ends of vertically adjacent nanostructure channels 315 in the source/drain recesses 305. The inner spacers 410 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonitride (SiOCN), and/or another dielectric material.

To form the inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410 in the cavities 405. In some implementations, the etch operation may result in the surfaces of the inner spacers 410 facing the source/drain recesses 305 being curved or recessed. In some implementations, the surfaces of the inner spacers 410 facing the source/drain recesses 305 are approximately flat such that the surfaces of the inner spacers 410 and the surfaces of the ends of the nanostructure channels 315 are approximately even and flush.

As indicated above, FIGS. 4A and 4B provided as an example. Other examples may differ from what is described with regard to FIGS. 4A and 4B.

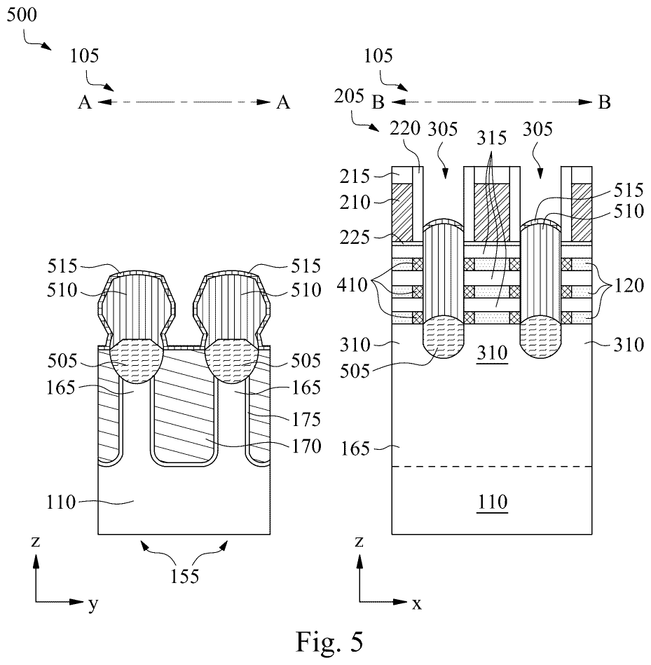

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of the source/drain recess 305, and a deposition tool may deposit a source/drain region 510 on the buffer region 505 in the source/drain recess 305. In some implementations, a deposition tool is used to deposit a capping layer 515 on the source/drain regions 510 in the source/drain recess 305.

A buffer region 505 may include silicon (Si), silicon doped with boron (Si:B) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

“Source/drain region” may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as a shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

A capping layer 515 may include silicon, silicon germanium, doped silicon, doped silicon germanium, and/or another material. The capping layer 515 may be included to reduce dopant diffusion and to protect an underlying source/drain region 510 in semiconductor processing operations for the semiconductor device 105 prior to contact formation. Moreover, the capping layer 515 may contribute to metal-semiconductor (e.g., silicide) alloy formation.

As indicated above, FIG. 5 is provided as an example. Other examples may differ from what is described with regard to FIG. 5.

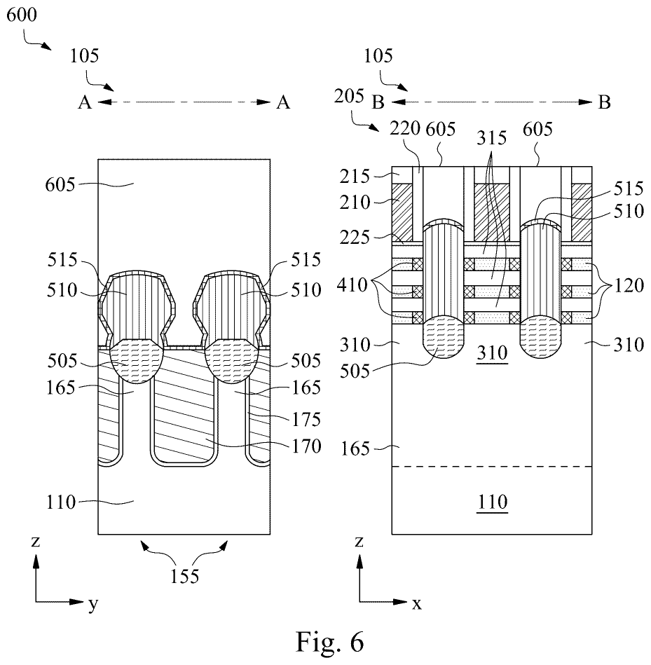

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 500 are performed after the processes described in connection with FIGS. 1A-5.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of and/or prevent damage to the source/drain regions 510 during a replacement gate process to replace the dummy gate structures 205. The dielectric layer 605 may be referred to as an ILD zero (ILD0) layer or another ILD layer.

In some implementations, a contact etch stop layer (CESL) is conformally deposited (e.g., by a deposition tool) over the source/drain regions 510 prior to formation of the dielectric layer 605. Alternatively, the capping layer 515 may be a CESL. The dielectric layer 605 is then formed on the CESL. The CESL may provide a mechanism to stop an etch process when forming contacts or vias for the source/drain regions 510. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As indicated above, FIG. 6 is provided as an example. Other examples may differ from what is described with regard to FIG. 6.

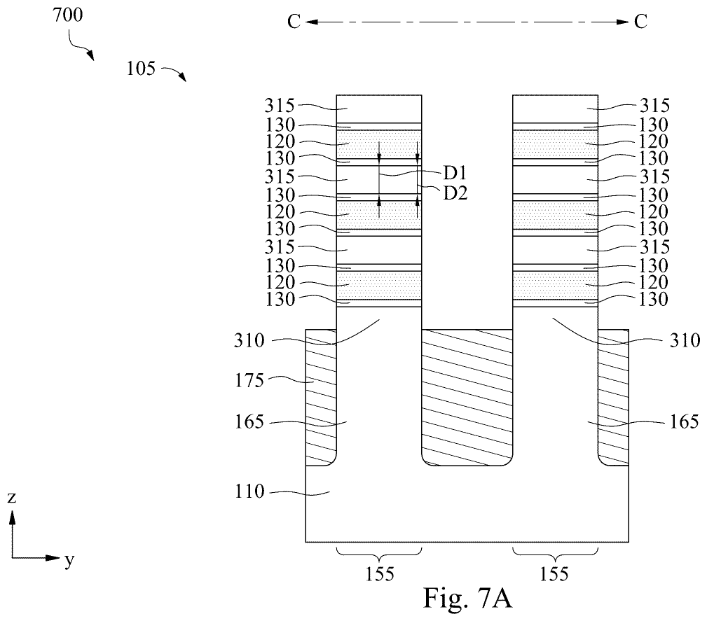

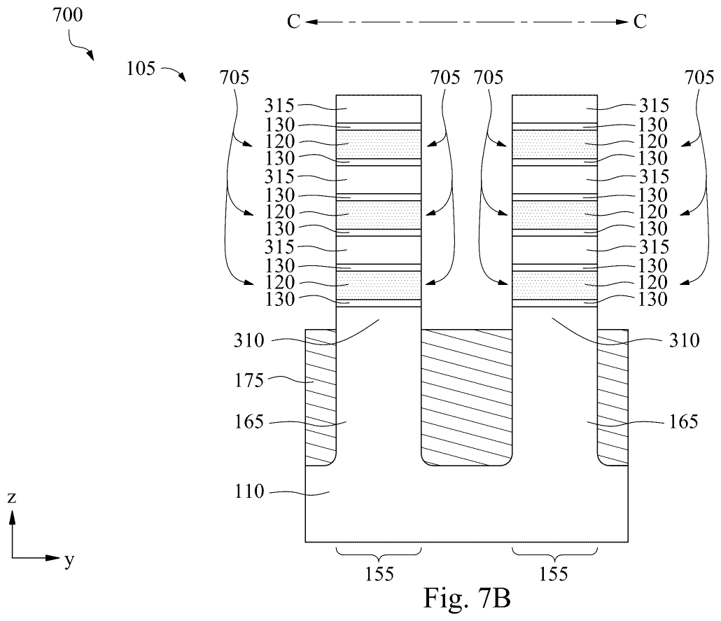

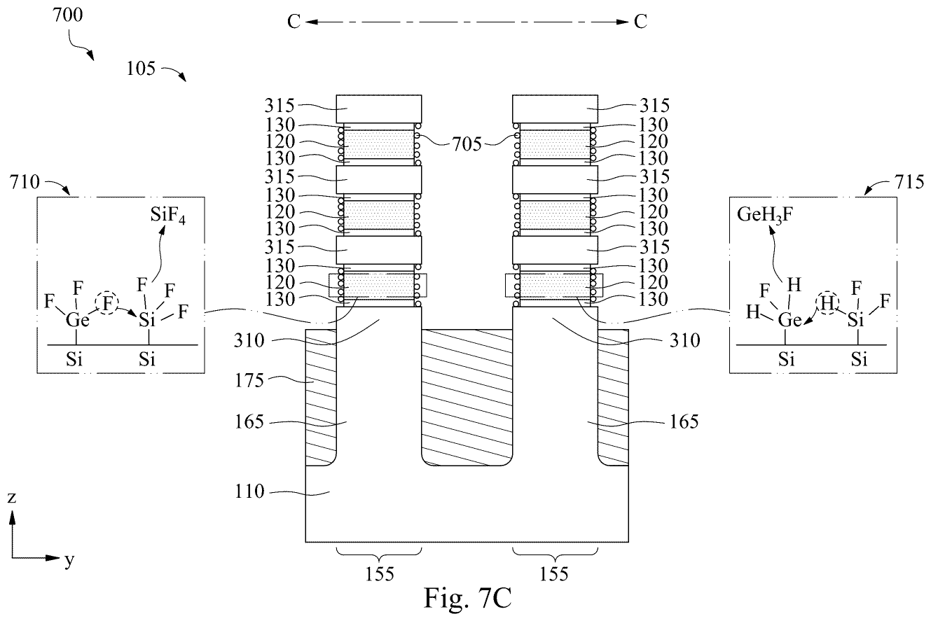

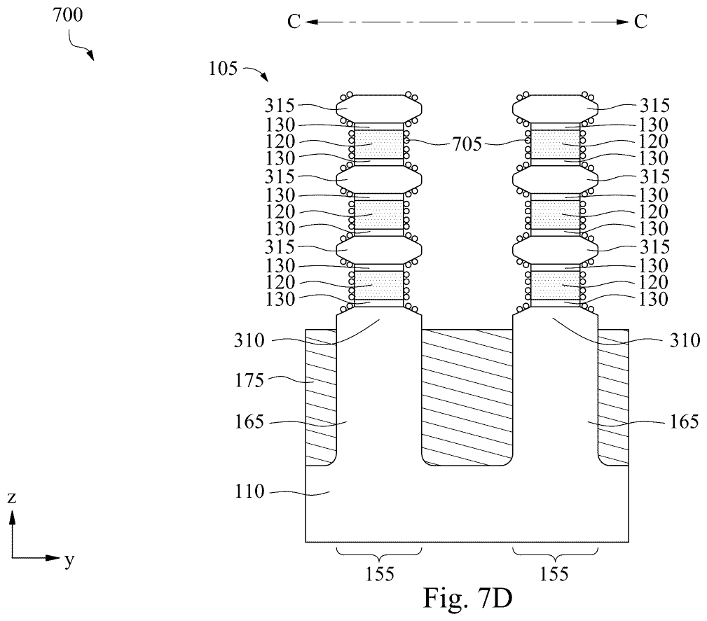

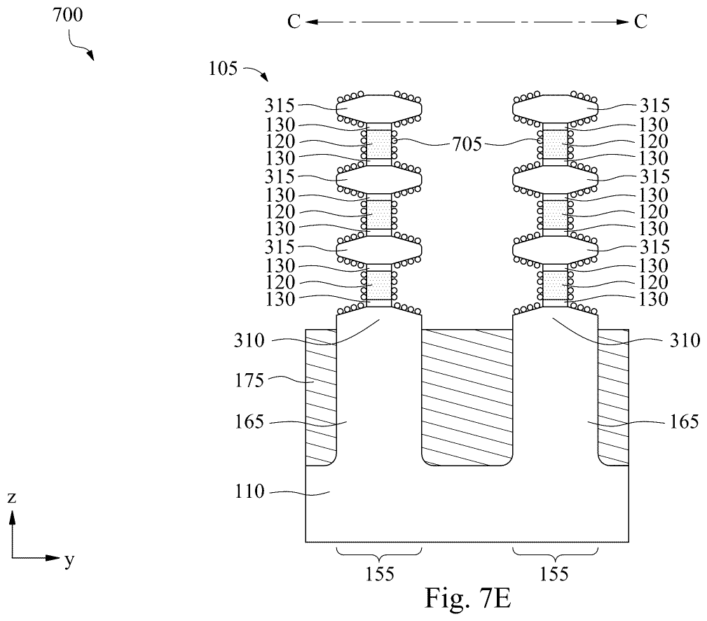

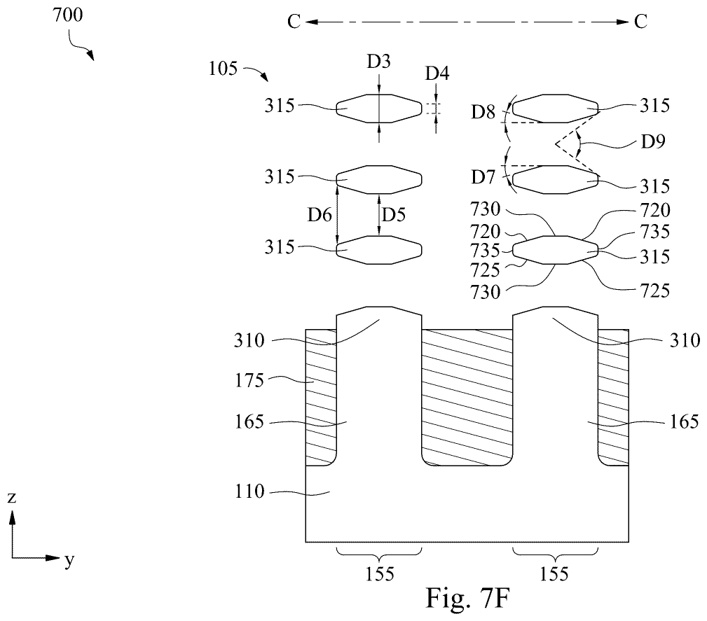

FIGS. 7A-7F are diagrams of an example implementation 700 of a nanosheet release process described herein. The nanosheet release process (e.g., a SiGe release process) is a process to remove the remaining portions of the sacrificial nanostructure layers 120 from between the nanostructure channels 315 of the semiconductor device 105. The nanosheet release process may be performed as part of a replacement gate (RPG) process that is performed to replace the dummy gate structures 205 with high-k/metal gate structures (e.g., the replacement gate structures) for the nanostructure transistors of the semiconductor device 105. FIGS. 7A-7F are each illustrated from the perspective of the cross-sectional plane C-C in FIG. 2. In some implementations, the operations described in connection with the example implementation 700 are performed after the operations described in connection with FIGS. 1A-6.

As shown FIG. 7A, a dummy gate removal operation may be performed prior to the nanosheet release process. The dummy gate removal operation includes removing the dummy gate structures 205 from the semiconductor device 105. The removal of the dummy gate structures 205 leaves behind openings (or recesses) between the dielectric layers 605, and provides access to the underlying sacrificial nanostructure layers 120 for the nanosheet removal process. The dummy gate structures 205 may be removed in one or more etch operations. Such etch operations may include a plasma etch technique, a wet chemical etch technique, and/or another type of etch technique.

As further shown in FIG. 7A, the nanostructure channels 315 may each have a dimension D1 and a dimension D2. The dimension D1 corresponds to a z-direction (vertical) thickness at the centers of the nanostructure channels 315 (e.g., centers along the y-direction width of the nanostructure channels 315), and the dimension D2 corresponds to a z-direction (vertical) thickness at the edges of the nanostructure channels 315 (e.g., the outer edges along the y-direction width of the nanostructure channels 315). Prior to the nanosheet release process, the z-direction thickness at the centers of the nanostructure channels 315 and the z-direction thickness at the edges of the nanostructure channels 315 are approximately equal thicknesses (e.g., dimension D1≈dimension D2).

As shown in FIGS. 7B-7F, the nanosheet release process may include performing an etch operation to laterally etch the sacrificial nanostructure layers 120 to remove the sacrificial nanostructure layers 120 from between vertically adjacent nanostructure channels 315.

As shown in FIG. 7B, the etch operation may include providing an etchant 705 around the exposed portions of the sacrificial nanostructure layers 120 and using the etchant 705 to laterally etch the sacrificial nanostructure layers 120. The semiconductor device 105 may be placed in a processing chamber of an etch tool, and the etchant 705 may be provided into the processing chamber as a mixture of process gasses that react with each other and/or with the material of the sacrificial nanostructure layers 120 to etch the sacrificial nanostructure layers 120. In some implementations, the pressure in the processing chamber may be included in a range of approximately 100 millitorr to approximately 2500 millitorr. However, other ranges and values are within the scope of the present disclosure.

The etchant 705 may include a gas-based etchant that includes a combination of a fluorine-based etchant (e.g., an F2 gas) and a hydrofluoric acid etchant (e.g., an HF gas). Other gases, such as purge gasses, carrier gasses, and/or other reactant gasses may also be provided into the processing chamber during the etch operation. Such gasses may include an argon (Ar) gas, an ammonia (NH₃) gas, a chlorine trifluoride (ClF₃) gas, and/or a nitrogen (N2) gas, among other examples. In some implementations, the total gas flow rate into the processing chamber may range up to approximately 1300 standard cubic centimeters per minute (sccm) during the etch operation. However, other values and/or ranges for the total gas flow rate during the etch operation are within the scope of the present disclosure.

As shown in FIGS. 7C-7E, the etchant 705 may laterally etch the sacrificial nanostructure layers 120 in the etch operation starting at the outer edges of the sacrificial nanostructure layers 120 and etching toward the centers of the sacrificial nanostructure layers 120 until the sacrificial nanostructure layers 120 are fully removed (or substantially fully removed). The etchant 705 may also etch and remove the intermixing layers 130 from the nanostructure channels 315. In some implementations, the etch operation is performed for a time duration of approximately 20 seconds to approximately 150 seconds to ensure that the sacrificial nanostructure layers 120 are fully removed. However, other ranges and values are within the scope of the present disclosure.

The etchant 705 may be used to etch the sacrificial nanostructure layers 120 and the intermixing layers 130 by removing silicon (Si) and germanium (Ge) from the sacrificial nanostructure layers 120 and the intermixing layers 130. The removal of silicon (Si) from the sacrificial nanostructure layers 120 and in the intermixing layers 130 may result from a reaction between the fluorine-based etchant (e.g., the F₂ gas) in the etchant 705 and the silicon germanium (SiGe) in the sacrificial nanostructure layers 120 and in the intermixing layers 130:

$$S i G e + {F}_{2} \to G e {F}_{3} + S i {F}_{3} \to G e {F}_{2} + S i {F}_{4}$$

As shown in connection with reference number 710 in FIG. 7C, the fluorine-based etchant (e.g., the F₂ gas) in the etchant 705 may attach to the silicon (Si) and the germanium (Ge) in the sacrificial nanostructure layers 120 and in the intermixing layers 130 to respectively form germanium trifluoride (GeF₃) and silicon trifluoride (SiF₃). A fluorine migration (F-migration) may occur where a fluorine (F) atom migrates from a germanium trifluoride molecule to a silicon trifluoride molecule, resulting in formation of germanium difluoride (GeF₂) and a silicon tetrafluoride (SiF₄) gas. The silicon tetrafluoride gas is removed from the semiconductor device 105, resulting in removal of silicon (Si) from the sacrificial nanostructure layers 120 and the intermixing layers 130. The fluorine (F) atom migration may occur at an energy in a range of approximately 0.3 electron-volts (eV) to approximately 0.35 eV. However, other values and/or ranges for the energy of the fluorine (F) atom migration are within the scope of the present disclosure. The fluorine (F) atom migration may be an exothermic process in which a change in enthalpy (ΔH) is included in a range of approximately −1.75 eV to approximately −2.0 eV. However, other values and/or ranges for the change in enthalpy are within the scope of the present disclosure.

The removal of germanium (Ge) from the sacrificial nanostructure layers 120 and in the intermixing layers 130 may result from a reaction between a combination of the fluorine-based etchant (e.g., the F₂ gas) and the hydrofluoric acid etchant (e.g., the HF gas) in the etchant 705 and the silicon germanium (SiGe) in the sacrificial nanostructure layers 120 and in the intermixing layers 130:

$$S i G e + {F}_{2} + H F \to G e {H}_{2} F + S i H {F}_{2} \to G e {H}_{3} F + S i {F}_{2}$$

As shown in connection with reference number 715 in FIG. 7C, the fluorine (F) in the fluorine-based etchant (e.g., the F₂ gas) and/or in the hydrofluoric acid etchant (e.g., the HF gas) may attach to the silicon (Si) and the germanium (Ge) in the sacrificial nanostructure layers 120 and in the intermixing layers 130. Moreover, the hydrogen in the hydrofluoric acid etchant of the etchant 705 may attach to the silicon (Si) and the germanium (Ge) in the sacrificial nanostructure layers 120 and in the intermixing layers 130. The fluorine and the hydrogen react with the germanium to form germanium dihydrogen fluoride (GeH₃F) and silicon hydrogen difluoride (SiHF₂). A hydrogen migration (H-migration) may occur where a hydrogen (H) atom migrates from a silicon hydrogen difluoride molecule to a germanium dihydrogen fluoride molecule, resulting in formation of a germanium trihydrogen fluoride (GeH₃F) gas and silicon difluoride (SiF₂). The germanium trihydrogen fluoride gas is removed from the semiconductor device 105, resulting in removal of germanium (Ge) from the sacrificial nanostructure layers 120 and the intermixing layers 130. The hydrogen (H) atom migration may occur at an energy in a range of approximately 0.9 eV to approximately 1.0 eV. However, other values and/or ranges for the energy of the fluorine (F) atom migration are within the scope of the present disclosure. The hydrogen (H) atom migration may be an exothermic process in which a change in enthalpy (ΔH) is included in a range of approximately −0.75 eV to approximately −0.9 eV. However, other values and/or ranges for the change in enthalpy are within the scope of the present disclosure.

In some implementations, the gas flow rate of the fluorine-based etchant (e.g., the F₂ gas) into the processing chamber during the etch operation may range up to approximately 300 sccm to achieve a sufficient etch rate of silicon (Si) and germanium (Ge) in the sacrificial nanostructure layers 120 and in the intermixing layers 130. However, other values and ranges for the gas flow rate of the fluorine-based etchant are within the scope of the present disclosure.

In some implementations, the gas flow rate of the hydrofluoric acid etchant (e.g., the HF gas) into the processing chamber during the etch operation may range up to approximately 50 sccm to achieve a sufficient etch rate of germanium (Ge) in the sacrificial nanostructure layers 120 and in the intermixing layers 130. However, other values and ranges for the gas flow rate of the hydrofluoric acid etchant are within the scope of the present disclosure.

As further shown in FIGS. 7C-7E, portions of the nanostructure channels 315 are also etched during the etch operation to remove the sacrificial nanostructure layers 120. The removal of material from the tops and bottoms of the nanostructure channels 315 results in the nanostructure channels 315 having a tapered or curved cross-sectional profile along the width of the nanostructure channels 315 (e.g., along the y-direction). As described above, the etchant 705 laterally etches the sacrificial nanostructure layers 120 starting at the edges of the sacrificial nanostructure layers 120 and continuing through to the centers of the sacrificial nanostructure layers 120. Thus, the etchant 705 is in contact with the edges of the nanostructure channels 315 for a longer time duration than with the centers of the nanostructure channels 315 along the y-direction. The different time durations of exposure to the etchant 705 result in a greater amount of etching (and thus, a greater amount of material removal from) the edges of the nanostructure channels 315 than at the centers of the nanostructure channels 315. This results in the tapered or curved cross-sectional profile along the width of the nanostructure channels 315 (e.g., along the y-direction).

As described above, the removal of silicon (Si) from the sacrificial nanostructure layers 120 and from the intermixing layers 130 involves the fluorine (F) migration between molecules formed from the silicon (Si) and the germanium (Ge) in the sacrificial nanostructure layers 120 and from the intermixing layers 130. The nanostructure channels 315, however, may not include germanium (Ge) and instead may include only silicon (Si). To achieve removal of silicon (Si) from the nanostructure channels 315 without the presence of germanium (Ge), the etch operation may be performed at a high temperature to provide sufficient energy to achieve the removal of silicon (Si) from the nanostructure channels 315 using the fluorine-based etchant (e.g., the F₂ gas) in the etchant 705.

For example, the temperature in the processing chamber may be elevated to a temperature that greater than 50 degrees Celsius and up to approximately 75 degrees Celsius. The etch operation may be performed while the temperature in the processing chamber is in this range to achieve the following reaction between the fluorine-based etchant (e.g., the F₂ gas) in the etchant 705 and the silicon (Si) in the nanostructure channels 315:

$$2 {F}_{2} + S i \to S i {F}_{4}$$

where the fluorine-based etchant (e.g., the F₂ gas) in the etchant 705 and the silicon (Si) in the nanostructure channels 315 react to form a silicon tetrafluoride (SiF₄) gas. The silicon tetrafluoride gas is removed from the semiconductor device 105, resulting in removal of silicon (Si) from the nanostructure channels 315. The reaction may occur at an energy in a range of approximately 1.1 electron-volts (eV) to approximately 1.2 eV. However, other values and/or ranges for the reaction are within the scope of the present disclosure.

FIG. 7F illustrates the cross-sectional profile of the nanostructure channels 315 after the etch operation. As shown in FIG. 7F, the nanostructure channels 315 may each have top sloped segments 720 and bottom sloped segments 725. A top sloped segment 720 may correspond to a cross-sectional segment between a center 730 of a nanostructure channel 315 and an outer edge 735 of the nanostructure channel 315 along the y-direction. The top sloped segment 720 is a part of a top surface of the nanostructure channel 315, and is sloped or angled between the center 730 and the outer edge 735 of the nanostructure channel 315. Alternatively, the top sloped segment 720 may be a curved segment. A bottom sloped segment 725 may correspond to a cross-sectional segment between a center 730 of a nanostructure channel 315 and an outer edge 735 of the nanostructure channel 315 along the y-direction. The bottom sloped segment 725 is a part of a bottom surface of the nanostructure channel 315, and is sloped or angled between the center 730 and the outer edge 735 of the nanostructure channel 315. Alternatively, the bottom sloped segment 725 may be a curved segment.

As further shown in FIG. 7F, a nanostructure channel 315 may have a dimension D3 and a dimension D4. The dimension D3 corresponds to a z-direction (vertical) thickness at the center 730 of the nanostructure channel 315 (e.g., centers along the y-direction width of the nanostructure channel 315), and the dimension D4 corresponds to a z-direction (vertical) thickness at an outer edge 735 of the nanostructure channel 315 (e.g., the outer edge along the y-direction width of the nanostructure channel 315). Since the nanostructure channels 315 were etched during the etch operation of the nanosheet release process, the z-direction thickness at the outer edges 735 the nanostructure channel 315 after the nanosheet release process (e.g., after the etch operation of the nanosheet release process) is less than the z-direction thickness at the outer edges 735 the nanostructure channel 315 prior to the nanosheet release process (e.g., dimension D4<dimension D2).

Moreover, and as indicated above, the different time durations of exposure to the etchant 705 at the center 730 and at the outer edges 735 result in a greater amount of etching (and thus, a greater amount of material removal from) the outer edges 735 of the nanostructure channel 315 than at the center 730 of a nanostructure channel 315. Thus, the z-direction thickness at the outer edges 735 of the nanostructure channel 315 after the nanosheet release process is less than the z-direction thickness at the center 730 of the nanostructure channel 315 after the nanosheet release process (e.g., dimension D4<dimension D3). Accordingly, the z-direction thickness of the nanostructure channel 315 decreases along the top sloped segments 720 and the bottom sloped segments 725 in the y-direction from the center 730 of the nanostructure channel 315 to the outer edges 735 of the nanostructure channel 315. In some implementations, the transition may be a uniform linear transition (e.g., the top sloped segments 720 and the bottom sloped segments 725 are angled straight lines) or a non-uniform transition (e.g., top sloped segments 720 and the bottom sloped segments 725 are curved).

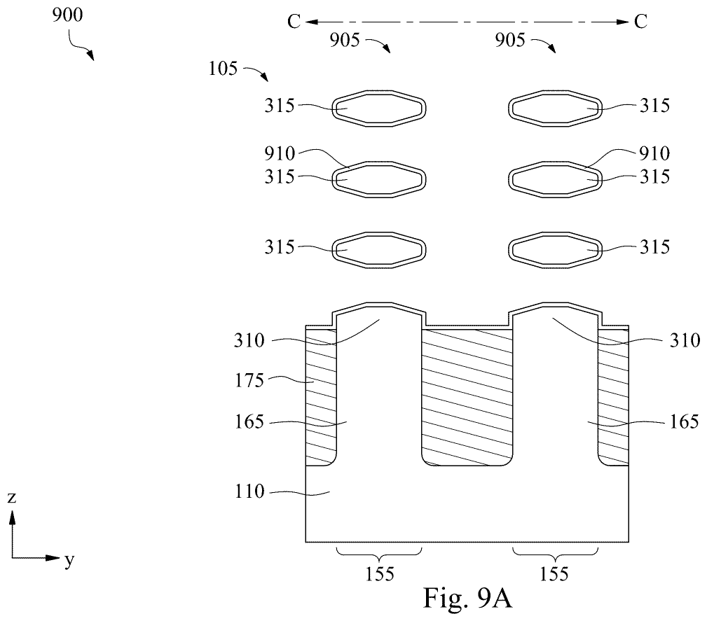

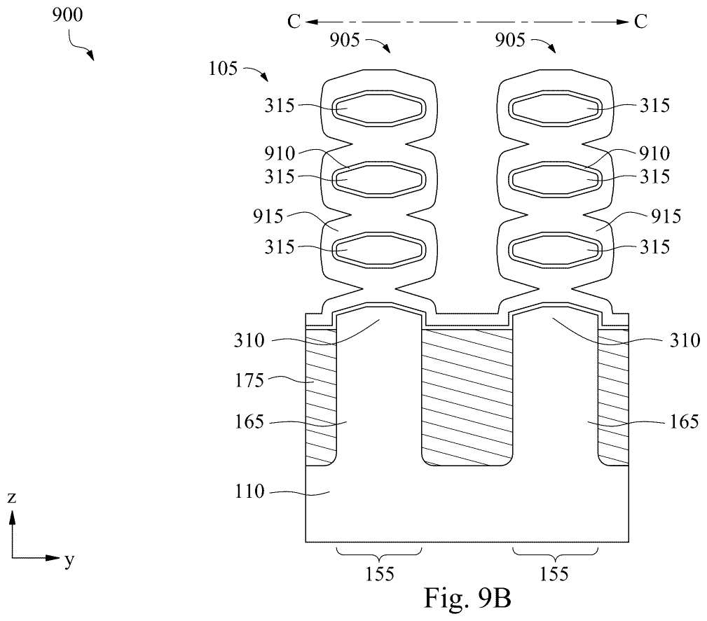

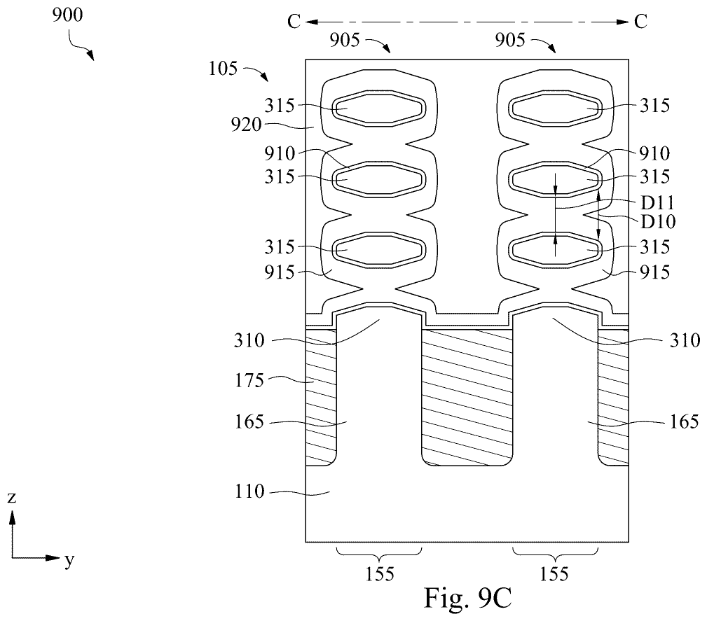

Because of the different z-direction thicknesses at the centers 730 and the outer edges 735 of the nanostructure channels 315, the vertical (z-direction) spacing between vertically adjacent (e.g., adjacent in the z-direction) nanostructure channels 315 may also be different at the centers 730 of the nanostructure channels 315 than at the outer edges 735 of the nanostructure channels 315. In particular, a vertical (z-direction) spacing (indicated in FIG. 7F as dimension D5) at the centers 730 of vertically adjacent nanostructure channels 315 may be less than a vertical (z-direction) spacing (indicated in FIG. 7F as dimension D6) at the outer edges 735 of the vertically adjacent nanostructure channels 315. The greater vertical spacing at the outer edges 735 of the vertically adjacent nanostructure channels 315 provides a greater area in which material of gate structures may flow into the spaces between vertically adjacent nanostructure channels 315, thereby improving the gap-filling performance when forming the gate structures. An example implementation of forming gate structures for the semiconductor device 105 is illustrated and described in connection with FIGS. 9A-9C.

As further shown in FIG. 7F, a top sloped segment 720 of a second nanostructure channel 315 may have an angle (indicated in FIG. 7F as dimension D7) relative to the center 730 of the top surface of the first nanostructure channel 315, and a bottom sloped segment 725 of a first nanostructure channel 315 vertically adjacent to the first nanostructure channel 315 may have an angle (indicated in FIG. 7F as dimension D8) relative to the center 730 of the bottom surface of the second nanostructure channel 315. These angles result in a larger angle (indicated in FIG. 7F as dimension D9) between the outer edges 735 of the first and second nanostructure channels 315 (relative to a central point between the first and second nanostructure channels 315 than if the first and second nanostructure channels 315 have uniform z-direction (vertical) thicknesses. The greater angle between the outer edges 735 provides a greater area in which material of gate structures may flow into the spaces between the first and second nanostructure channels 315, thereby improving the gap-filling performance when forming the gate structures.

As indicated above, FIGS. 7A-7F are provided as an example. Other examples may differ from what is described with regard to FIGS. 7A-7F.

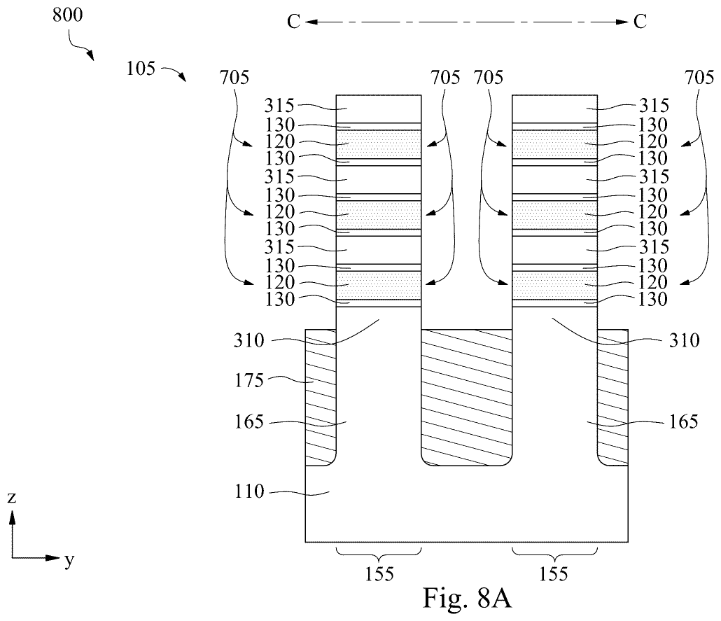

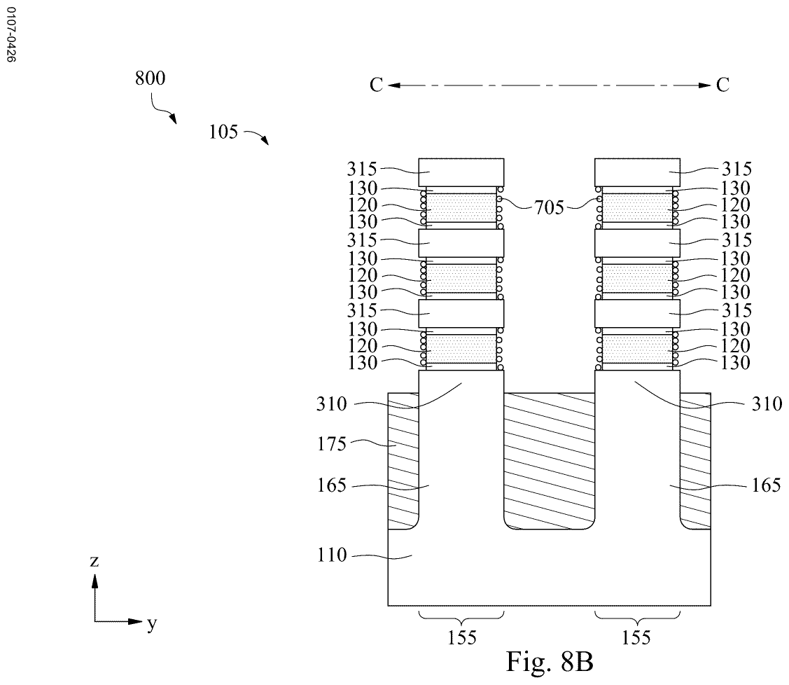

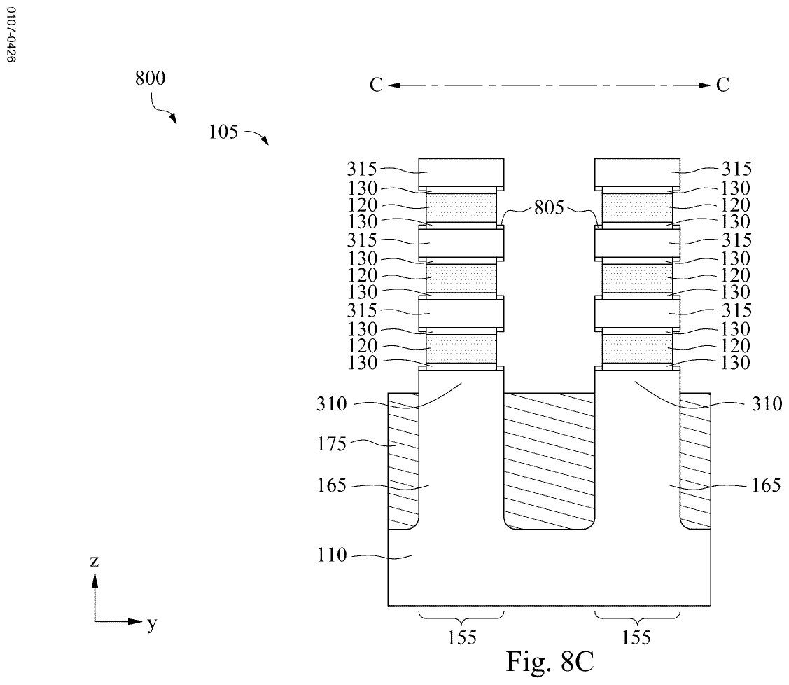

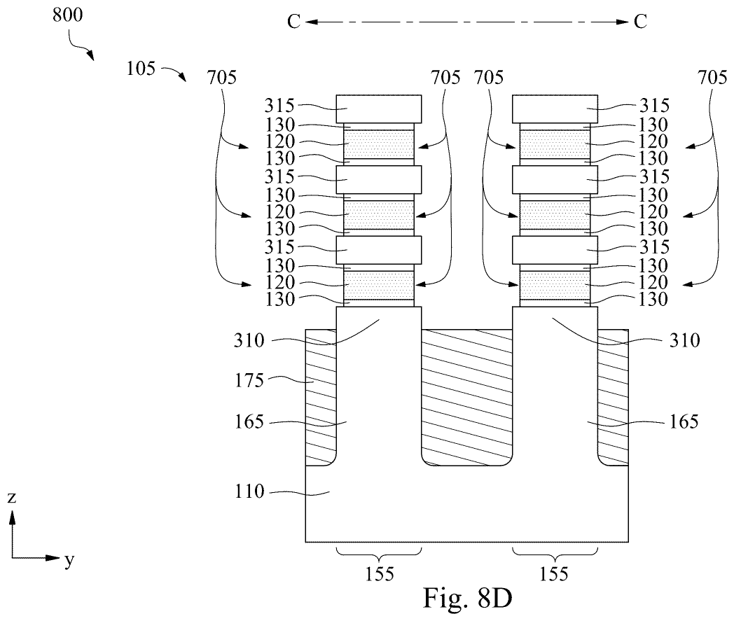

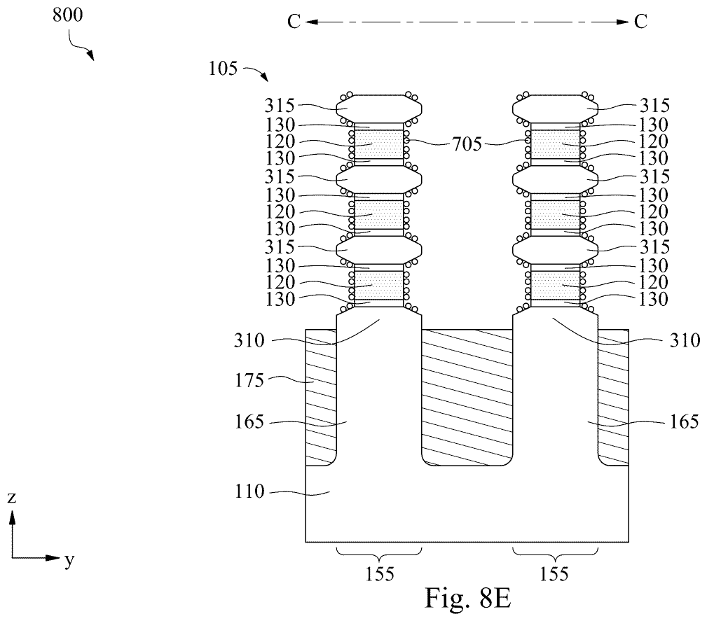

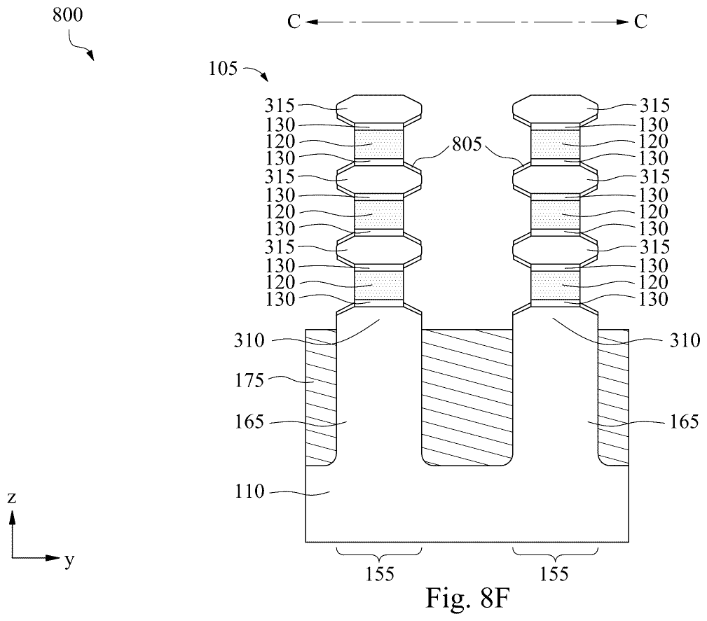

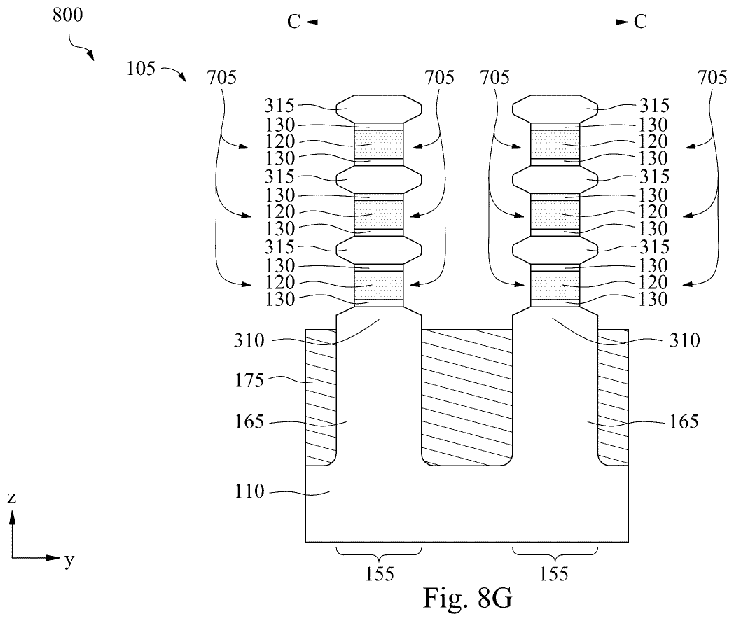

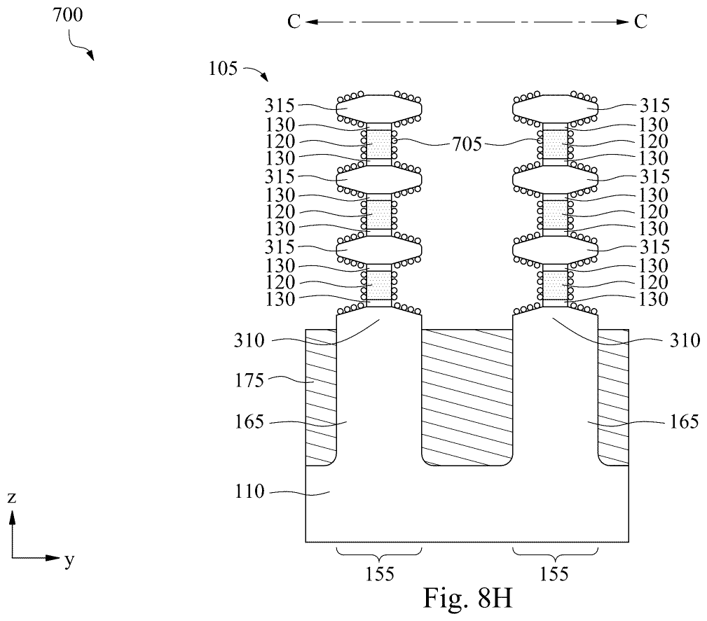

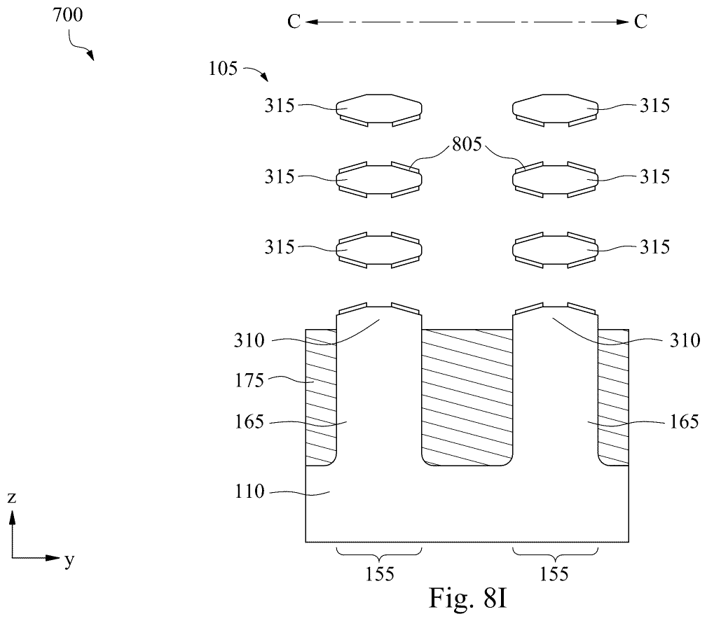

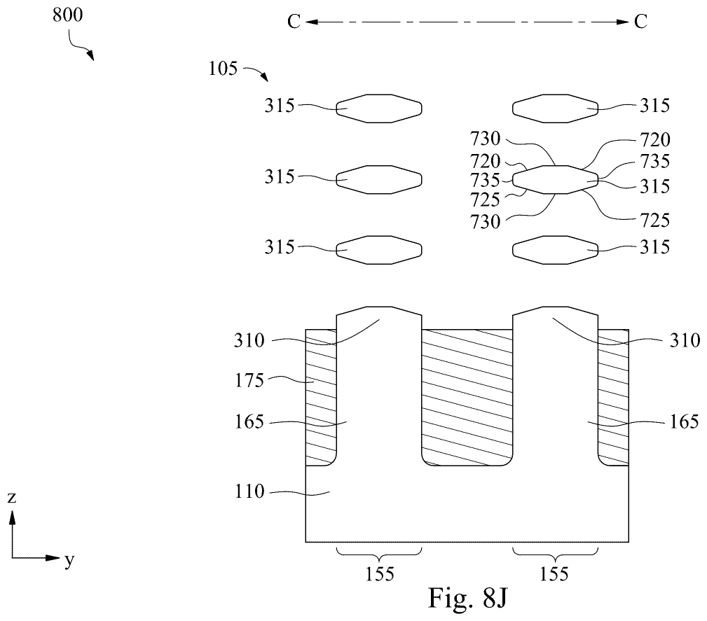

FIGS. 8A-8J are diagrams of an example implementation 800 of a nanosheet release process described herein. The example implementation 800 illustrated and described in connection with FIGS. 8A-8J is an alternative to the nanosheet release process illustrated and described in connection with FIGS. 7A-7F. FIGS. 8A-8J are each illustrated from the perspective of the cross-sectional plane C-C in FIG. 2. In some implementations, the operations described in connection with the example implementation 700 are performed after the operations described in connection with FIGS. 1A-6.

The nanosheet release process illustrated and described in connection with FIGS. 8A-8J is performed using lower-temperature processes than the nanosheet release process illustrated and described in connection with FIGS. 7A-7F. The nanosheet release process illustrated and described in connection with FIGS. 8A-8J is a cyclic process that includes a plurality of etch-purge cycles that are performed at temperatures of approximately 50 degrees Celsius or less, such as at temperatures of approximately 30 degrees Celsius to approximately 50 degrees Celsius. However, other values and ranges for the temperatures of the example implementation 800 of the nanosheet release process illustrated and described in connection with FIGS. 8A-8J are within the scope of the present disclosure. Performing the nanosheet release process at temperatures of approximately 50 degrees Celsius or less may reduce the likelihood of gas etchants used in the nanosheet release process etching through the inner spacers 410 and damaging the source/drain regions 510 of the semiconductor device 105. However, performing the nanosheet release process at temperatures greater than approximately 50 degrees Celsius, as described in connection with FIGS. 7A-7F, may enable the tapered or curved cross-sectional profile to be achieved for the nanostructure channels 315 using fewer process steps and fewer etchants, thus resulting in reduced process complexity, time, and/or cost.

FIGS. 8A-8C illustrate a first etch-purge cycle of the cyclic process, FIGS. 8D-8F illustrate a second etch-purge cycle of the cyclic process, and FIGS. 8G-8I illustrate a third etch-purge cycle of the cyclic process. However, the quantity of etch-purge cycles of the cyclic process illustrated in FIGS. 8A-8I is an example, and other quantities are within the scope of the present disclosure. The etch-purge cycles of the cyclic process may be performed “in-situ” in that the semiconductor device 105 is maintained in the same processing chamber (e.g., without removing the semiconductor device 105 from the processing chamber) for the entirety of the etch-purge cycles of the cyclic process.

As shown in FIGS. 8A and 8B, the first etch-purge cycle of the cyclic process may include a first etch operation in which the etchant 705 is used to remove first portions of the sacrificial nanostructure layers 120. Portions of the intermixing layers 130 and/or portions of the nanostructure channels 315 may also be removed in the first etch operation.

As shown in FIG. 8C, byproducts 805 may deposit onto the nanostructure channels 315 during the first etch operation. The byproducts 805 may correspond to etching byproducts that form from removal of material from the sacrificial nanostructure layers 120, the intermixing layers 130, and/or the nanostructure channels 315 during the first etch operation. These byproducts 805 may inhibit further etching of the nanostructure channels 315. Accordingly, the first etch-purge cycle of the cyclic process may further include a first purge operation that is performed to remove the byproducts 805 so that the nanostructure channels 315 can be further etched with the etchant 705.

The first purge operation may include providing a purge gas into the processing chamber and pumping the purge gas out of the processing chamber (e.g., with the purge gas carrying the byproducts 805 out of the processing chamber). The purge gas may include one or more inert gases such as argon (Ar) and/or nitrogen (N₂), among other examples. In some implementations, a flow rate of argon gas into the processing chamber may range up to approximately 500 sccm. However, other ranges and values for the flow rate of the argon gas are within the scope of the present disclosure. In some implementations, a flow rate of nitrogen gas into the processing chamber may range up to approximately 500 sccm. However, other ranges and values for the flow rate of the nitrogen gas are within the scope of the present disclosure.

As shown in FIGS. 8D and 8E, the second etch-purge cycle of the cyclic process may include a second etch operation in which the etchant 705 is used to remove second portions of the sacrificial nanostructure layers 120. Portions of the intermixing layers 130 and/or portions of the nanostructure channels 315 may also be removed in the second etch operation.

As shown in FIG. 8F, byproducts 805 may deposit onto the nanostructure channels 315 during the second etch operation. Accordingly, the second etch-purge cycle of the cyclic process may further include a second purge operation that is performed to remove the byproducts 805 so that the nanostructure channels 315 can be further etched with the etchant 705.

As shown in FIGS. 8G and 8H, the third etch-purge cycle of the cyclic process may include a third etch operation in which the etchant 705 is used to remove third portions of the sacrificial nanostructure layers 120. Portions of the intermixing layers 130 and/or portions of the nanostructure channels 315 may also be removed in the third etch operation.

As shown in FIG. 8I, byproducts 805 may deposit onto the nanostructure channels 315 during the third etch operation. Accordingly, the third etch-purge cycle of the cyclic process may further include a third purge operation that is performed to remove the byproducts 805 so that the nanostructure channels 315 can be further etched with the etchant 705.

In some implementations, two or more etch operations in the cycle process may be performed with the same process parameters, such as the same time duration, the same chamber pressure, the same temperature, and/or the same etchant flow rates, among other examples. In some implementations, two or more etch operations in the cycle process may be performed with different process parameters to achieve a particular cross-section profile for the nanostructure channels 315. For example, two or more etch operations in the cycle process may be performed for different time durations, with different chamber pressures, at different chamber temperatures, and/or using different etchant flow rates, among other examples.

FIG. 8J illustrates the cross-sectional profile of the nanostructure channels 315 after the etch operation. As shown in FIG. 8J, the nanostructure channels 315 may each have top sloped segments 720 and bottom sloped segments 725. A top sloped segment 720 may correspond to a cross-sectional segment between a center 730 of a nanostructure channel 315 and an outer edge 735 of the nanostructure channel 315 along the y-direction. The top sloped segment 720 is a part of a top surface of the nanostructure channel 315, and is sloped or angled between the center 730 and the outer edge 735 of the nanostructure channel 315. Alternatively, the top sloped segment 720 may be a curved segment. A bottom sloped segment 725 may correspond to a cross-sectional segment between a center 730 of a nanostructure channel 315 and an outer edge 735 of the nanostructure channel 315 along the y-direction. The bottom sloped segment 725 is a part of a bottom surface of the nanostructure channel 315, and is sloped or angled between the center 730 and the outer edge 735 of the nanostructure channel 315. Alternatively, the bottom sloped segment 725 may be a curved segment.

As indicated above, FIGS. 8A-8J are provided as an example. Other examples may differ from what is described with regard to FIGS. 8A-8J.

FIGS. 9A-9C are diagrams of an example implementation 900 of a gate formation process described herein. The gate formation process may be performed as part of the replacement gate process that is performed to replace the dummy gate structures 205 with gate structures 905 (e.g., high-k/metal gate structures) for the nanostructure transistors of the semiconductor device 105. FIGS. 9A-9C are each illustrated from the perspective of the cross-sectional plane C-C in FIG. 2. In some implementations, the operations described in connection with the example implementation 900 are performed after one or more of the operations described in connection with FIGS. 1A-8J.

As shown in FIG. 9A, a gate dielectric layer 910 of a gate structure 905 may be formed around the nanostructure channels 315. In some implementations, the gate dielectric layer 910 is also formed on the mesa regions 310. A deposition tool may be used to deposit the gate dielectric layer 910 using a PVD technique, an ALD technique, a CVD technique, an oxidation technique, and/or another suitable deposition technique. In some implementations, the gate dielectric layer 910 is a high-k gate dielectric layer that includes one or more high-k materials (e.g., dielectric materials having a dielectric constant greater than silicon dioxide (SiO₂-dielectric constant of approximately 3.9). Examples include lanthanum oxide (LaₓO_{y} such as La₂O₃), hafnium oxide (HfOₓ such as HfO₂), zirconium oxide (ZrOₓ such as ZrO₂), and/or aluminum oxide (AlₓO_{y} such as Al₂O₃), among other examples. Additionally and/or alternatively, silicon dioxide (SiO₂) and/or another dielectric material may be used instead of a high-k dielectric material. In some implementations, the gate dielectric layer 910 may have a thickness that is included in a range of approximately 0.5 nanometers to approximately 3 nanometers. However, other values for the range are within the scope of the present disclosure.

As shown in FIG. 9B, a work function metal layer 915 of the gate structure 905 is formed on the gate dielectric layer 910. A deposition tool may be used to deposit the work function metal layer 915 using a CVD technique, a PVD technique, an ALD technique, an electroplating technique, and/or another suitable deposition technique.

The work function metal layer 915 may be included for tuning the work function of the gate structure 905. In some implementations, the gate structure 905 is a p-type gate structure for a p-type metal-oxide-semiconductor (PMOS) nanostructure transistor, and the work function metal layer 915 is a p-type work function metal layer. In these implementations, the work function metal layer 915 may include one or more p-type metals, such as tungsten (W), cobalt (Co), titanium nitride (TiN), tungsten nitride (WN), and/or another metal having a work function that is greater than approximately 4.7 eV, among other examples, for tuning the work function of the gate structure 905 such that the work function is adjusted close to the valance band (E_{V}) of the material of the nanostructure channels 315. In some implementations, the gate structure 905 is an n-type gate structure for an n-type metal-oxide-semiconductor (NMOS) nanostructure transistor, and the work function metal layer 915 is an n-type work function metal layer. In these implementations, the work function metal layer 915 may include one or more n-type metals, such as titanium aluminum (TiAl) and/or titanium aluminum carbon (TiAlC), among other examples, for tuning the work function of the gate structure 905 such that the work function is close to the conduction band (E_{C}) of the material of the nanostructure channels 315.

The work function metal layer 915 may be formed such that the work function metal layer 915 wraps around the nanostructure channels 315 on one or more sides of the nanostructure channels 315. In some implementations, material of the work function metal layer 915 is deposited between vertically adjacent nanostructure channels 315. In some implementations, the work function metal layer 915 is merged between vertically adjacent nanostructure channels 315. The tapered or curved cross-sectional profile achieved for the nanostructure channels 315 using the nanosheet release techniques described in connection with FIGS. 7A-7F and/or 8A-8J provides for improved gap-filling performance for depositing the work function metal layer 915 between vertically adjacent nanostructure channels 315, which reduces the likelihood of seams/voids being formed in the work function metal layer 915 between the vertically adjacent nanostructure channels 315. Alternatively, the work function metal layer 915 is not merged and is instead spaced apart between vertically adjacent nanostructure channels 315 such that the work function metal layer 915 wrapping around each nanostructure channel 315 is spaced apart from the work function metal layers 915 around vertically adjacent nanostructure channels 315.

As shown in FIG. 9C, a gate electrode layer 920 of the gate structure 905 may be formed over the work function metal layer 915. The gate electrode layer 920 may be formed such that the gate electrode layer 920 wraps around the nanostructure channels 315 on one or more sides of the nanostructure channels 315. Material of the gate electrode layer 920 may be deposited between vertically adjacent nanostructure channels 315. The tapered or curved cross-sectional profile achieved for the nanostructure channels 315 using the nanosheet release techniques described in connection with FIGS. 7A-7F and/or 8A-8J provides for improved gap-filling performance for depositing the gate electrode layer 920 between vertically adjacent nanostructure channels 315, which reduces the likelihood of seams/voids being formed in the gate electrode layer 920 between the vertically adjacent nanostructure channels 315.

The gate electrode layer 920 includes one or more electrically conductive metal materials, such as ruthenium (Ru), tungsten (W), cobalt (Co), copper (Cu), and/or molybdenum (Mo), among other examples. A deposition tool may be used to deposit the gate electrode layer 920 using a CVD technique, a PVD technique, an ALD technique, an electroplating technique, and/or another suitable deposition technique. The gate electrode layer 920 may be deposited in one or more deposition operations. In some implementations, a seed layer is first deposited, and the gate electrode layer 920 is deposited on the seed layer. In some implementations, a planarization tool may be used to planarize the gate electrode layer 920 after the gate electrode layer 920 is deposited.

Because of the different z-direction thicknesses at the centers 730 and the outer edges 735 of the nanostructure channels 315, the z-direction (vertical) thickness of the gate structure 905 between vertically adjacent (e.g., adjacent in the z-direction) nanostructure channels 315 may also be different at the centers 730 of the nanostructure channels 315 than at the outer edges 735 of the nanostructure channels 315. In particular, a z-direction (vertical) thickness (indicated in FIG. 9C as dimension D10) of the gate structure 905 at the centers 730 of vertically adjacent nanostructure channels 315 may be greater than a z-direction (vertical) thickness (indicated in FIG. 9C as dimension D11) of the gate structure 905 at the outer edges 735 of the vertically adjacent nanostructure channels 315.

As indicated above, FIGS. 9A-9C are provided as an example. Other examples may differ from what is described with regard to FIGS. 9A-9C.

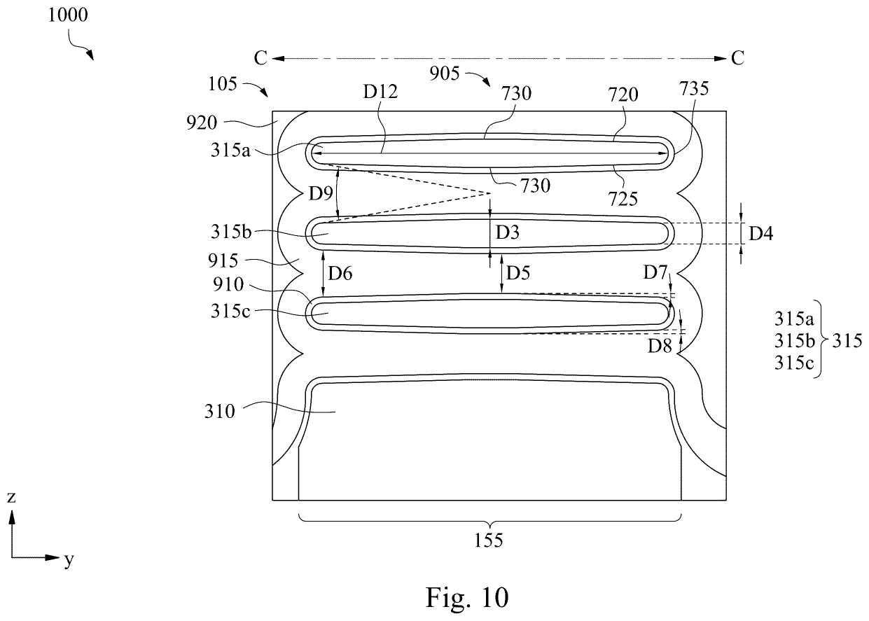

FIG. 10 is a diagram of an example implementation 1000 of the semiconductor device 105 described herein. As shown in FIG. 10, the semiconductor device 105 may include a plurality of nanostructure channels 315 (arranged in the z-direction) in the semiconductor device 105. The semiconductor device 105 includes a gate structure 905 wrapping around the nanostructure channels 315 and a gate dielectric layer 910 between the nanostructure channels 315 and the gate structure 905. The gate structure 905 may include a work function metal layer 915 and a gate electrode layer 920.

A z-direction thickness (dimension D3) at a center 730 of a nanostructure channel 315 may be greater than a z-direction thickness (dimension D4) at outer edges 735 of the nanostructure channel 315. In some implementations, the z-direction thickness at the center 730 of the nanostructure channel 315 is included in a range of approximately 3 nanometers to approximately 8 nanometers, whereas the z-direction thickness at the outer edges 735 of the nanostructure channel 315 is included in a range of approximately 2 nanometers to approximately 7 nanometers. However, other values and ranges are within the scope of the present disclosure.

A z-direction distance or spacing (dimension D6) between outer edges 735 of vertically adjacent nanostructure channels 315 may be greater than a z-direction distance or spacing (dimension D5) at centers 730 of the vertically adjacent nanostructure channels 315. In some implementations, the z-direction distance or spacing at the centers 730 of the vertically adjacent nanostructure channels 315 is included in a range of approximately 8 nanometers to approximately 13 nanometers, whereas the z-direction distance or spacing at the outer edges 735 of the vertically adjacent nanostructure channel 315 is included in a range of approximately 9 nanometers to approximately 13 nanometers. However, other values and ranges are within the scope of the present disclosure.

In some implementations, the gate structure 905 is an n-type gate structure and the nanostructure channels 315 may have a sheet width (indicated in FIG. 10 as dimension D12) included in a range of approximately 30 nanometers to approximately 80 nanometers. In these implementations, an average z-direction thickness of a top nanostructure channel 315a, an average z-direction thickness of a middle nanostructure channel 315b, and an average z-direction thickness of a bottom nanostructure channel 315c may each be included in a range of approximately 3 nanometers to approximately 7 nanometers. However, other values and ranges are within the scope of the present disclosure.

Moreover, in these implementations, a difference between the z-direction thickness (dimension D3) at the center 730 of the top nanostructure channel 315a and a z-direction thickness (dimension D4) at an outer edge 735 of the top nanostructure channel 315a may be included in a range of approximately 0 nanometers to approximately 1.5 nanometers. A difference between the z-direction thickness (dimension D3) at the center 730 of the middle nanostructure channel 315b and a z-direction thickness (dimension D4) at an outer edge 735 of the middle nanostructure channel 315b may be included in a range of approximately 1 nanometer to approximately 2.5 nanometers. A difference between the z-direction thickness (dimension D3) at the center 730 of the bottom nanostructure channel 315c and a z-direction thickness (dimension D4) at an outer edge 735 of the bottom nanostructure channel 315c may be included in a range of approximately 1 nanometer to approximately 2.5 nanometers. However, other values and ranges are within the scope of the present disclosure.

Moreover, in these implementations, an average spacing or distance between the top nanostructure channel 315a and the middle nanostructure channel 315b, an average spacing or distance between the middle nanostructure channel 315b and the bottom nanostructure channel 315c, and an average spacing or distance between the bottom nanostructure channel 315c and the mesa region 310 may each be included in a range of approximately 8 nanometers to approximately 13 nanometers. However, other values and ranges are within the scope of the present disclosure.

Moreover, in these implementations, a difference between the z-direction distance or spacing (dimension D6) at the outer edges 735 of the top nanostructure channel 315a and the middle nanostructure channel 315b and a z-direction distance or spacing (dimension D5) at the centers 730 of the top nanostructure channel 315a and the middle nanostructure channel 315b may be included in a range of approximately 0 nanometers to approximately 2 nanometers. A difference between the z-direction distance or spacing (dimension D6) at the outer edges 735 of the middle nanostructure channel 315b and the bottom nanostructure channel 315c and a z-direction distance or spacing (dimension D5) at the centers 730 of the middle nanostructure channel 315b and the bottom nanostructure channel 315c may be included in a range of approximately 0.5 nanometers to approximately 2.5 nanometers. A difference between the z-direction distance or spacing (dimension D6) at the outer edges 735 of the bottom nanostructure channel 315c and the mesa region 310 and a z-direction distance or spacing (dimension D5) at the centers 730 of the bottom nanostructure channel 315c and the mesa region 310 may be included in a range of approximately 0 nanometers to approximately 2 nanometers. However, other values and ranges are within the scope of the present disclosure.

Moreover, in these implementations, the angles (dimension D7) of the top sloped segments 720 of the top nanostructure channel 315a, the middle nanostructure channel 315b, and the bottom nanostructure channel 315c, and the angles (dimension D8) of the bottom sloped segments 725 of the top nanostructure channel 315a, the middle nanostructure channel 315b, and the bottom nanostructure channel 315c may each be included in a range of approximately 1 degree to approximately 6 degrees. In this range, sufficient gap-filling performance for achieving a low likelihood of gap/void formation in the gate structure 905 may be achieved. However, other values and ranges are within the scope of the present disclosure.

Moreover, in these implementations, an angle (dimension D9) between an outer edge 735 of the top nanostructure channel 315a and an outer edge 735 of the middle nanostructure channel 315b, an angle between an outer edge 735 of the middle nanostructure channel 315b and an outer edge 735 of the bottom nanostructure channel 315c, and an angle between an outer edge 735 of the bottom nanostructure channel 315c and an outer edge 735 of the mesa region 310 may each be included in a range of approximately 15 degrees to approximately 23 degrees. In this range, sufficient gap-filling performance for achieving a low likelihood of gap/void formation in the gate structure 905 may be achieved. However, other values and ranges are within the scope of the present disclosure.

In some implementations, the gate structure 905 is a p-type gate structure and the nanostructure channels 315 may have a sheet width (dimension D12) included in a range of approximately 30 nanometers to approximately 80 nanometers. In these implementations, an average z-direction thickness of a top nanostructure channel 315a may be included in a range of approximately 4 nanometers to approximately 8 nanometers, whereas an average z-direction thickness of a middle nanostructure channel 315b and an average z-direction thickness of a bottom nanostructure channel 315c may each be included in a range of approximately 3.5 nanometers to approximately 7.5 nanometers. However, other values and ranges are within the scope of the present disclosure.

Moreover, in these implementations, a difference between the z-direction thickness (dimension D3) at the center 730 of the top nanostructure channel 315a and a z-direction thickness (dimension D4) at an outer edge 735 of the top nanostructure channel 315a may be included in a range of approximately 0 nanometers to approximately 1.5 nanometers. A difference between the z-direction thickness (dimension D3) at the center 730 of the middle nanostructure channel 315b and a z-direction thickness (dimension D4) at an outer edge 735 of the middle nanostructure channel 315b may be included in a range of approximately 1 nanometer to approximately 2.5 nanometers. A difference between the z-direction thickness (dimension D3) at the center 730 of the bottom nanostructure channel 315c and a z-direction thickness (dimension D4) at an outer edge 735 of the bottom nanostructure channel 315c may be included in a range of approximately 1 nanometer to approximately 2.5 nanometers. However, other values and ranges are within the scope of the present disclosure.

Moreover, in these implementations, an average spacing or distance between the top nanostructure channel 315a and the middle nanostructure channel 315b, an average spacing or distance between the middle nanostructure channel 315b and the bottom nanostructure channel 315c, and an average spacing or distance between the bottom nanostructure channel 315c and the mesa region 310 may each be included in a range of approximately 7 nanometers to approximately 12 nanometers. However, other values and ranges are within the scope of the present disclosure.

Moreover, in these implementations, a difference between the z-direction distance or spacing (dimension D6) at the outer edges 735 of the top nanostructure channel 315a and the middle nanostructure channel 315b and a z-direction distance or spacing (dimension D5) at the centers 730 of the top nanostructure channel 315a and the middle nanostructure channel 315b may be included in a range of approximately 0 nanometers to approximately 2 nanometers. A difference between the z-direction distance or spacing (dimension D6) at the outer edges 735 of the middle nanostructure channel 315b and the bottom nanostructure channel 315c and a z-direction distance or spacing (dimension D5) at the centers 730 of the middle nanostructure channel 315b and the bottom nanostructure channel 315c may be included in a range of approximately 0.5 nanometers to approximately 2.5 nanometers. A difference between the z-direction distance or spacing (dimension D6) at the outer edges 735 of the bottom nanostructure channel 315c and the mesa region 310 and a z-direction distance or spacing (dimension D5) at the centers 730 of the bottom nanostructure channel 315c and the mesa region 310 may be included in a range of approximately 0 nanometers to approximately 2 nanometers. However, other values and ranges are within the scope of the present disclosure.

Moreover, in these implementations, the angles (dimension D7) of the top sloped segments 720 of the top nanostructure channel 315a, the middle nanostructure channel 315b, and the bottom nanostructure channel 315c, and the angles (dimension D8) of the bottom sloped segments 725 of the top nanostructure channel 315a, the middle nanostructure channel 315b, and the bottom nanostructure channel 315c may each be included in a range of approximately 1 degree to approximately 6 degrees. In this range, sufficient gap-filling performance for achieving a low likelihood of gap/void formation in the gate structure 905 may be achieved. However, other values and ranges are within the scope of the present disclosure.

Moreover, in these implementations, an angle (dimension D9) between an outer edge 735 of the top nanostructure channel 315a and an outer edge 735 of the middle nanostructure channel 315b, an angle between an outer edge 735 of the middle nanostructure channel 315b and an outer edge 735 of the bottom nanostructure channel 315c, and an angle between an outer edge 735 of the bottom nanostructure channel 315c and an outer edge 735 of the mesa region 310 may each be included in a range of approximately 15 degrees to approximately 23 degrees. In this range, sufficient gap-filling performance for achieving a low likelihood of gap/void formation in the gate structure 905 may be achieved. However, other values and ranges are within the scope of the present disclosure.

In some implementations, the gate structure 905 is a p-type gate structure or an n-type gate structure, and the nanostructure channels 315 may have a sheet width (dimension D12) included in a range of approximately 5 nanometers to approximately 30 nanometers. In these implementations, an average z-direction thickness of a top nanostructure channel 315a may be included in a range of approximately 3 nanometers to approximately 7 nanometers, whereas an average z-direction thickness of a middle nanostructure channel 315b and an average z-direction thickness of a bottom nanostructure channel 315c may each be included in a range of approximately 2 nanometers to approximately 6 nanometers. However, other values and ranges are within the scope of the present disclosure.

Moreover, in these implementations, a difference between the z-direction thickness (dimension D3) at the center 730 of the top nanostructure channel 315a and a z-direction thickness (dimension D4) at an outer edge 735 of the top nanostructure channel 315a may be included in a range of approximately −0.5 nanometers to approximately 1 nanometer. A difference between the z-direction thickness (dimension D3) at the center 730 of the middle nanostructure channel 315b and a z-direction thickness (dimension D4) at an outer edge 735 of the middle nanostructure channel 315b may be included in a range of approximately −0.5 nanometers to approximately 0.5 nanometers. A difference between the z-direction thickness (dimension D3) at the center 730 of the bottom nanostructure channel 315c and a z-direction thickness (dimension D4) at an outer edge 735 of the bottom nanostructure channel 315c may be included in a range of approximately −0.5 nanometers to approximately 0.5 nanometers. However, other values and ranges are within the scope of the present disclosure.

Moreover, in these implementations, an average spacing or distance between the top nanostructure channel 315a and the middle nanostructure channel 315b, an average spacing or distance between the middle nanostructure channel 315b and the bottom nanostructure channel 315c, and an average spacing or distance between the bottom nanostructure channel 315c and the mesa region 310 may each be included in a range of approximately 8 nanometers to approximately 13 nanometers. However, other values and ranges are within the scope of the present disclosure.

Moreover, in these implementations, a difference between the z-direction distance or spacing (dimension D6) at the outer edges 735 of the top nanostructure channel 315a and the middle nanostructure channel 315b and a z-direction distance or spacing (dimension D5) at the centers 730 of the top nanostructure channel 315a and the middle nanostructure channel 315b may be included in a range of approximately −0.5 nanometers to approximately 0.5 nanometers. A difference between the z-direction distance or spacing (dimension D6) at the outer edges 735 of the middle nanostructure channel 315b and the bottom nanostructure channel 315c and a z-direction distance or spacing (dimension D5) at the centers 730 of the middle nanostructure channel 315b and the bottom nanostructure channel 315c may be included in a range of approximately −0.5 nanometers to approximately 0.5 nanometers. A difference between the z-direction distance or spacing (dimension D6) at the outer edges 735 of the bottom nanostructure channel 315c and the mesa region 310 and a z-direction distance or spacing (dimension D5) at the centers 730 of the bottom nanostructure channel 315c and the mesa region 310 may be included in a range of approximately −0.5 nanometers to approximately 0.5 nanometers. However, other values and ranges are within the scope of the present disclosure.

Moreover, in these implementations, the angles (dimension D7) of the top sloped segments 720 of the top nanostructure channel 315a, the middle nanostructure channel 315b, and the bottom nanostructure channel 315c, and the angles (dimension D8) of the bottom sloped segments 725 of the top nanostructure channel 315a, the middle nanostructure channel 315b, and the bottom nanostructure channel 315c may each be included in a range of approximately 0 degrees to approximately 2 degrees. In this range, sufficient gap-filling performance for achieving a low likelihood of gap/void formation in the gate structure 905 may be achieved. However, other values and ranges are within the scope of the present disclosure.

Moreover, in these implementations, an angle (dimension D9) between an outer edge 735 of the top nanostructure channel 315a and an outer edge 735 of the middle nanostructure channel 315b, an angle between an outer edge 735 of the middle nanostructure channel 315b and an outer edge 735 of the bottom nanostructure channel 315c, and an angle between an outer edge 735 of the bottom nanostructure channel 315c and an outer edge 735 of the mesa region 310 may each be included in a range of approximately 35 degrees to approximately 50 degrees. In this range, sufficient gap-filling performance for achieving a low likelihood of gap/void formation in the gate structure 905 may be achieved. However, other values and ranges are within the scope of the present disclosure.

As indicated above, FIG. 10 is provided as an example. Other examples may differ from what is described with regard to FIG. 10.

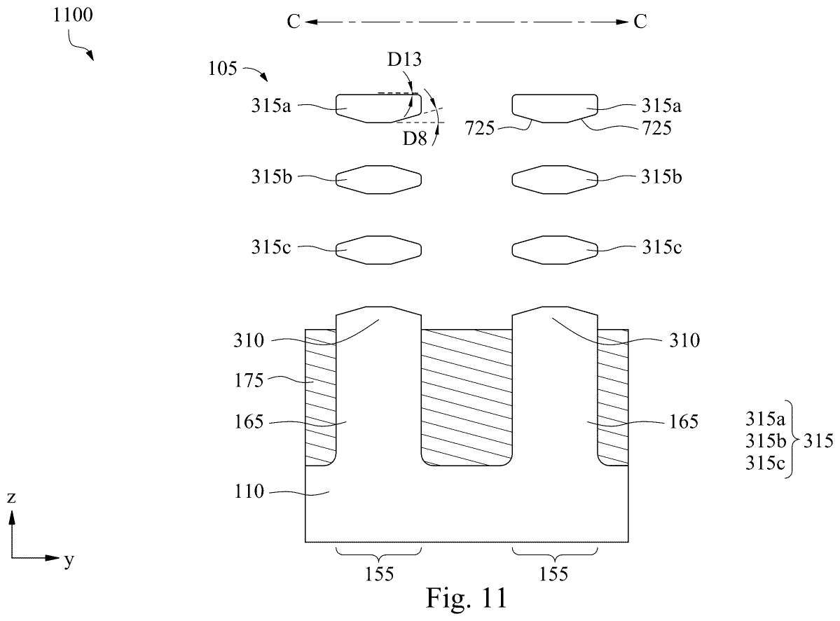

FIG. 11 is a diagram of an example implementation 1100 of the semiconductor device 105 described herein. As shown in FIG. 11, the semiconductor device 105 may include a plurality of nanostructure channels 315 arranged in the z-direction) in the semiconductor device 105. The top nanostructure channels 315a may differ from the nanostructure channels 315 in FIGS. 7F and 8J in that the top nanostructure channels 315a in the example implementation 1100 have substantially flat top surfaces. Thus, an angle (indicated in FIG. 11 as dimension D13) of the top surface of the top nanostructure channels 315a in the example implementation 1100 may be included in a range of approximately 0 degrees to approximately 2 degrees. However, other ranges and values are within the scope of the present disclosure.

As indicated above, FIG. 11 is provided as an example. Other examples may differ from what is described with regard to FIG. 11.

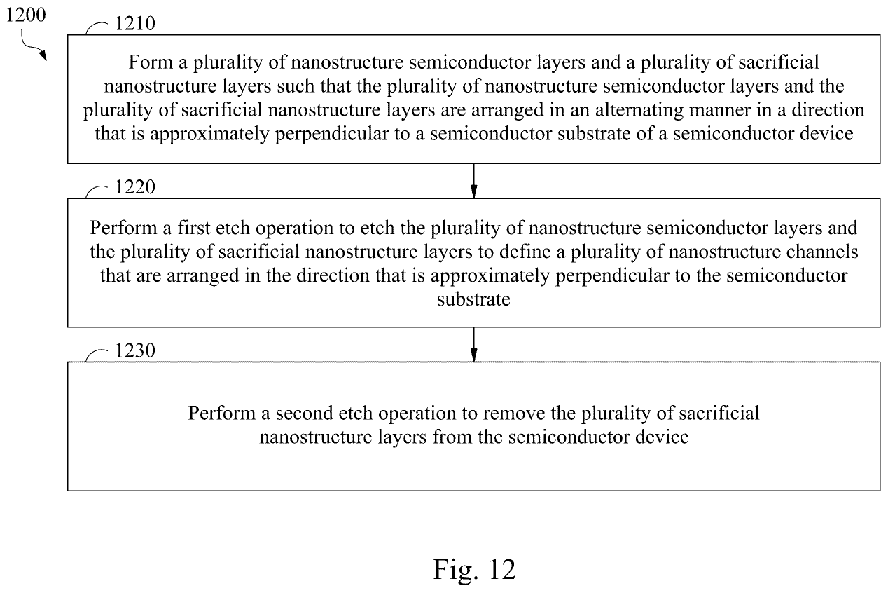

FIG. 12 is a flowchart of an example process 1200 associated with forming a semiconductor device described herein. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device (block 1210). For example, one or more semiconductor processing tools may be used to form a plurality of nanostructure semiconductor layers (e.g., nanostructure channel layers 125) and a plurality of sacrificial nanostructure layers (e.g., sacrificial nanostructure layers 120) such that the plurality of nanostructure semiconductor layers and the plurality of sacrificial nanostructure layers are arranged in an alternating manner in a direction (e.g., a z-direction) that is approximately perpendicular to a semiconductor substrate (e.g., a semiconductor substrate 110) of a semiconductor device (e.g., a semiconductor device 105), as described herein.

As further shown in FIG. 12, process 1200 may include performing a first etch operation to etch the plurality of nanostructure semiconductor layers and the plurality of sacrificial nanostructure layers to define a plurality of nanostructure channels that are arranged in the direction that is approximately perpendicular to the semiconductor substrate (block 1220). For example, one or more semiconductor processing tools may be used to perform a first etch operation to etch the plurality of nanostructure semiconductor layers and the plurality of sacrificial nanostructure layers to define a plurality of nanostructure channels (e.g., nanostructure channels 315) that are arranged in the direction that is approximately perpendicular to the semiconductor substrate, as described herein. In some implementations, the plurality of nanostructure channels and the plurality of sacrificial nanostructure layers are arranged in an alternating manner in the direction that is approximately perpendicular to the semiconductor substrate.

As further shown in FIG. 12, process 1200 may include performing a second etch operation to remove the plurality of sacrificial nanostructure layers from the semiconductor device (block 1230). For example, one or more semiconductor processing tools may be used to perform a second etch operation to remove the plurality of sacrificial nanostructure layers from the semiconductor device, as described herein. In some implementations, the second etch operation results in a nanostructure channel of the plurality of nanostructure channels having a first cross-sectional thickness (e.g., a dimension D3) at a center (e.g., a center 730) of the nanostructure channel and a second cross-sectional thickness (e.g., a dimension D4) at outer edges (e.g., at outer edges 735) of the nanostructure channel. In some implementations, the second cross-sectional thickness is less than the first cross-sectional thickness.

Process 1200 may include additional implementations, such as any single implementation or any combination of implementations described below and/or in connection with one or more other processes described elsewhere herein.

In a first implementation, the second cross-sectional thickness (e.g., a dimension D2) at the outer edges of the nanostructure channel is greater prior to the second etch operation than after the second etch operation (e.g., the dimension D4).

In a second implementation, alone or in combination with the first implementation, performing the second etch operation includes performing the second etch operation at a temperature that is greater than approximately 50 degrees Celsius and less than or approximately equal to 75 degrees Celsius.

In a third implementation, alone or in combination with one or more of the first and second implementations, performing the second etch operation includes performing the second etch operation using a fluorine-based etchant, where the fluorine-based etchant removes material from the plurality of nanostructure channels during the second etch operation.

In a fourth implementation, alone or in combination with one or more of the first through third implementations, performing the second etch operation includes performing the second etch operation using a hydrofluoric acid etchant, where the hydrofluoric acid etchant removes material from the plurality of sacrificial nanostructure layers during the second etch operation.

In a fifth implementation, alone or in combination with one or more of the first through fourth implementations, at least one of the fluorine-based etchant or the hydrofluoric acid etchant removes material from an intermixing layer (e.g., an intermixing layer 130) between the nanostructure channel and a sacrificial nanostructure layer of the plurality of sacrificial nanostructure layers.

In a sixth implementation, alone or in combination with one or more of the first through fifth implementations, a greater amount of material is removed from a center (e.g., a center 730) of the nanostructure channel than from outer edges (e.g., outer edges 735) of the nanostructure channel in the second etch operation.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

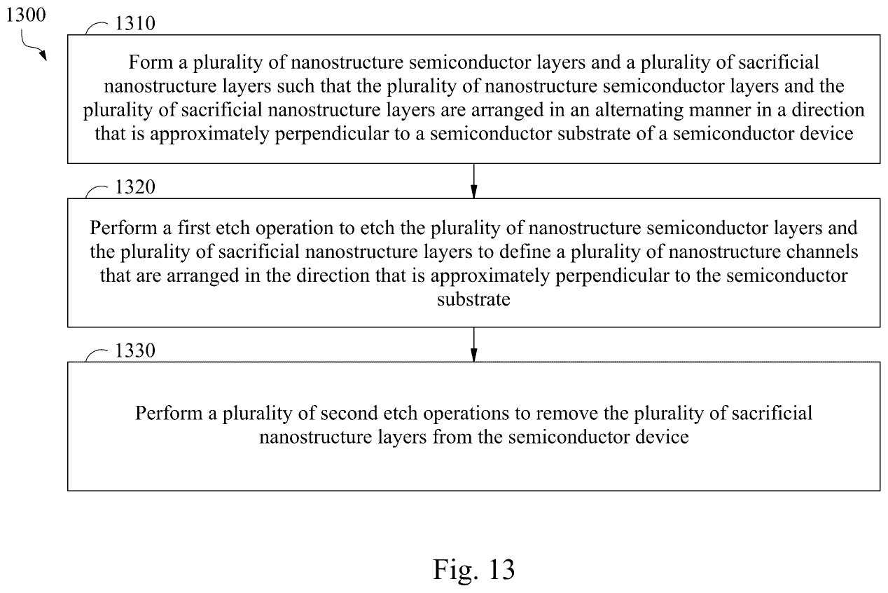

FIG. 13 is a flowchart of an example process 1300 associated with forming a semiconductor device described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device (block 1310). For example, one or more semiconductor processing tools may be used to form a plurality of nanostructure semiconductor layers (e.g., nanostructure channel layers 125) and a plurality of sacrificial nanostructure layers (e.g., sacrificial nanostructure layers 120) such that the plurality of nanostructure semiconductor layers and the plurality of sacrificial nanostructure layers are arranged in an alternating manner in a direction (e.g., a z-direction) that is approximately perpendicular to a semiconductor substrate (e.g., a semiconductor substrate 110) of a semiconductor device (e.g., a semiconductor device 105), as described herein.

As further shown in FIG. 13, process 1300 may include performing a first etch operation to etch the plurality of nanostructure semiconductor layers and the plurality of sacrificial nanostructure layers to define a plurality of nanostructure channels that are arranged in the direction that is approximately perpendicular to the semiconductor substrate (block 1320). For example, one or more semiconductor processing tools may be used to perform a first etch operation to etch the plurality of nanostructure semiconductor layers and the plurality of sacrificial nanostructure layers to define a plurality of nanostructure channels (e.g., nanostructure channels 315) that are arranged in the direction that is approximately perpendicular to the semiconductor substrate, as described herein. In some implementations, the plurality of nanostructure channels and the plurality of sacrificial nanostructure layers are arranged in an alternating manner in the direction that is approximately perpendicular to the semiconductor substrate.

As further shown in FIG. 13, process 1300 may include performing a plurality of second etch operations to remove the plurality of sacrificial nanostructure layers from the semiconductor device (block 1330). For example, one or more semiconductor processing tools may be used to perform a plurality of second etch operations to remove the plurality of sacrificial nanostructure layers from the semiconductor device, as described herein. In some implementations, the plurality of second etch operation results in top and bottom surfaces of a nanostructure channel of the plurality of nanostructure channels having sloped segments (e.g., top sloped segments 720, bottom sloped segments 725) between a center (e.g., a center 730) of the nanostructure channel and outer edges (e.g., outer edges 735) of the nanostructure channel.

Process 1300 may include additional implementations, such as any single implementation or any combination of implementations described below and/or in connection with one or more other processes described elsewhere herein.

In a first implementation, performing the plurality of second etch operations includes performing a third etch operation to remove first portions of the plurality of sacrificial nanostructure layers, and performing a fourth etch operation to remove second portions of the plurality of sacrificial nanostructure layers.

In a second implementation, alone or in combination with the first implementation, performing the plurality of second etch operations includes performing, prior to the fourth etch operation, a purge operation to remove byproducts resultant from the third etch operation.

In a third implementation, alone or in combination with one or more of the first and second implementations, performing the plurality of second etch operations includes performing the third etch operation, the purge operation, and the fourth etch operation in a same processing chamber.

In a fourth implementation, alone or in combination with one or more of the first through third implementations, performing the plurality of second etch operations includes performing the plurality of second etch operations at a temperature that is included in a range of approximately 30 degrees Celsius to approximately 50 degrees Celsius.

In a fifth implementation, alone or in combination with one or more of the first through fourth implementations, performing the plurality of second etch operations includes performing the plurality of second etch operations using a fluorine-based etchant and a hydrofluoric acid etchant.

In a sixth implementation, alone or in combination with one or more of the first through fifth implementations, the hydrofluoric acid etchant removes material from the plurality of sacrificial nanostructure layers during the plurality of second etch operations.

In a seventh implementation, alone or in combination with one or more of the first through sixth implementations, the fluorine-based etchant removes material from the plurality of nanostructure channels during the plurality of second etch operations.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, nanostructure channels of a nanostructure transistor are etched during a nanosheet release process for removing sacrificial nanostructure layers between the nanostructure channels. The nanostructure channels are etched such that the thickness of the nanostructure channels at the edges of the nanostructure channels is less than the thickness of the nanostructure channels at the centers of the nanostructure channels. This results in the nanostructure channels having a sloped/tapered or curved cross-sectional profile between the centers and the edges of the nanostructure channels. The resultant cross-section profile provides larger openings between vertically adjacent nanostructure channels for depositing material of a gate structure of the nanostructure transistor between vertically adjacent nanostructure channels of the nanostructure transistor. The larger openings increase the gap-filling performance for forming the gate structure, which reduces the likelihood of (and/or size of) seams and/or voids in the gate structure between vertically adjacent nanostructure channels. Thus, the techniques described herein may reduce gate resistance and/or gate capacitance of the nanostructure transistor, which may increase the performance of the nanostructure transistor.

As described in greater detail above, some implementations described herein provide a method. The method includes forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device. The method includes performing a first etch operation to etch the plurality of nanostructure semiconductor layers and the plurality of sacrificial nanostructure layers to define a plurality of nanostructure channels that are arranged in the direction that is approximately perpendicular to the semiconductor substrate, where the plurality of nanostructure channels and the plurality of sacrificial nanostructure layers are arranged in an alternating manner in the direction that is approximately perpendicular to the semiconductor substrate. The method includes performing a second etch operation to remove the plurality of sacrificial nanostructure layers from the semiconductor device, where the second etch operation results in a nanostructure channel of the plurality of nanostructure channels, having a first cross-sectional thickness at a center of the nanostructure channel and a second cross-sectional thickness at outer edges of the nanostructure channel, and where the second cross-sectional thickness is less than the first cross-sectional thickness.

As described in greater detail above, some implementations described herein provide a method. The method includes forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device. The method includes performing a first etch operation to etch the plurality of nanostructure semiconductor layers and the plurality of sacrificial nanostructure layers to define a plurality of nanostructure channels that are arranged in the direction that is approximately perpendicular to the semiconductor substrate, where the plurality of nanostructure channels and the plurality of sacrificial nanostructure layers are arranged in an alternating manner in the direction that is approximately perpendicular to the semiconductor substrate. The method includes performing a plurality of second etch operations to remove the plurality of sacrificial nanostructure layers from the semiconductor device, where the plurality of second etch operation results in top and bottom surfaces of a nanostructure channel of the plurality of nanostructure channels having sloped segments between a center of the nanostructure channel and outer edges of the nanostructure channel.

As described in greater detail above, some implementations described herein provide a semiconductor device. The semiconductor device includes a plurality of nanostructure channels arranged in a direction that is approximately perpendicular to a semiconductor substrate of the semiconductor device, where a first distance between outer edges of vertically adjacent nanostructure channels of the plurality of nanostructure channels is greater than a second distance between centers of the vertically adjacent nanostructure channels. The semiconductor device includes a gate structure wrapping around the plurality of nanostructure channels. The semiconductor device includes a first source/drain region adjacent to a first side of the gate structure. The semiconductor device includes a second source/drain region adjacent to a second side of the gate structure opposing the first side.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device;
performing a first etch operation to etch the plurality of nanostructure semiconductor layers and the plurality of sacrificial nanostructure layers to define a plurality of nanostructure channels that are arranged in the direction that is approximately perpendicular to the semiconductor substrate,
wherein the plurality of nanostructure channels and the plurality of sacrificial nanostructure layers are arranged in an alternating manner in the direction that is approximately perpendicular to the semiconductor substrate; and
performing a second etch operation to remove the plurality of sacrificial nanostructure layers from the semiconductor device,
wherein the second etch operation results in a nanostructure channel of the plurality of nanostructure channels, having a first cross-sectional thickness at a center of the nanostructure channel and a second cross-sectional thickness at outer edges of the nanostructure channel, and
wherein the second cross-sectional thickness is less than the first cross-sectional thickness.

2. The method of claim 1, wherein the second cross-sectional thickness at the outer edges of the nanostructure channel is greater prior to the second etch operation than after the second etch operation.

3. The method of claim 1, wherein performing the second etch operation comprises:
performing the second etch operation at a temperature that is greater than approximately 50 degrees Celsius and less than or approximately equal to 75 degrees Celsius.

4. The method of claim 3, wherein performing the second etch operation comprises:
performing the second etch operation using a fluorine-based etchant,
wherein the fluorine-based etchant removes material from the plurality of nanostructure channels during the second etch operation.

5. The method of claim 4, wherein performing the second etch operation comprises:
performing the second etch operation using a hydrofluoric acid etchant,
wherein the hydrofluoric acid etchant removes material from the plurality of sacrificial nanostructure layers during the second etch operation.

6. The method of claim 5, wherein at least one of the fluorine-based etchant or the hydrofluoric acid etchant removes material from an intermixing layer between the nanostructure channel and a sacrificial nanostructure layer of the plurality of sacrificial nanostructure layers.

7. The method of claim 1, wherein a greater amount of material is removed from the center of the nanostructure channel than from the outer edges of the nanostructure channel in the second etch operation.

8. A method, comprising:
forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device;
performing a first etch operation to etch the plurality of nanostructure semiconductor layers and the plurality of sacrificial nanostructure layers to define a plurality of nanostructure channels that are arranged in the direction that is approximately perpendicular to the semiconductor substrate,
wherein the plurality of nanostructure channels and the plurality of sacrificial nanostructure layers are arranged in an alternating manner in the direction that is approximately perpendicular to the semiconductor substrate; and
performing a plurality of second etch operations to remove the plurality of sacrificial nanostructure layers from the semiconductor device,
wherein the plurality of second etch operation results in top and bottom surfaces of a nanostructure channel of the plurality of nanostructure channels having sloped segments between a center of the nanostructure channel and outer edges of the nanostructure channel.

9. The method of claim 8, wherein performing the plurality of second etch operations comprises:
performing a third etch operation to remove first portions of the plurality of sacrificial nanostructure layers; and
performing a fourth etch operation to remove second portions of the plurality of sacrificial nanostructure layers.

10. The method of claim 9, wherein performing the plurality of second etch operations comprises:
performing, prior to the fourth etch operation, a purge operation to remove byproducts resultant from the third etch operation.

11. The method of claim 10, wherein performing the plurality of second etch operations comprises:
performing the third etch operation, the purge operation, and the fourth etch operation in a same processing chamber.

12. The method of claim 8, wherein performing the plurality of second etch operations comprises:
performing the plurality of second etch operations at a temperature that is included in a range of approximately 30 degrees Celsius to approximately 50 degrees Celsius.

13. The method of claim 8, wherein performing the plurality of second etch operations comprises:
performing the plurality of second etch operations using a fluorine-based etchant and a hydrofluoric acid etchant.

14. The method of claim 13, wherein the hydrofluoric acid etchant removes material from the plurality of sacrificial nanostructure layers during the plurality of second etch operations.

15. The method of claim 14, wherein the fluorine-based etchant removes material from the plurality of nanostructure channels during the plurality of second etch operations.

16. A semiconductor device, comprising:
a plurality of nanostructure channels arranged in a direction that is approximately perpendicular to a semiconductor substrate of the semiconductor device,
wherein a first distance between outer edges of vertically adjacent nanostructure channels of the plurality of nanostructure channels is greater than a second distance between centers of the vertically adjacent nanostructure channels;
a gate structure wrapping around the plurality of nanostructure channels;
a first source/drain region adjacent to a first side of the gate structure; and
a second source/drain region adjacent to a second side of the gate structure opposing the first side.

17. The semiconductor device of claim 16, wherein a first thickness of the gate structure between the outer edges of the vertically adjacent nanostructure channels is greater than a second thickness of the gate structure between the centers of the vertically adjacent nanostructure channels.

18. The semiconductor device of claim 16, wherein a first thicknesses of the outer edges of the vertically adjacent nanostructure channels is greater than second thicknesses of the centers of the vertically adjacent nanostructure channels.

19. The semiconductor device of claim 16, wherein an angle between a center of a nanostructure channel of the plurality of nanostructure channels and a sloped segment of the nanostructure channel is included in a range of approximately 1 degree to approximately 6 degrees.

20. The semiconductor device of claim 16, wherein a first angle between a center of a nanostructure channel of the plurality of nanostructure channels and a top sloped segment of the nanostructure channel, and a second angle between the center of the nanostructure channel and a bottom sloped segment, are different angles.
